(19) United States
(12) Patent Application Publication
(10) Pub. No.: US 2002/0007474 A1
(43) Pub. Date: Jan. 17, 2002

(54) Turbo-code decoding unit and turbo-code encoding/decoding unit

(75) Inventors: Hachiro Fujita, Tokyo (JP); Yoshikuni Miyata, Tokyo (JP); Takahiko Nakamura, Tokyo (JP); Hideo Yoshida, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 09/816,074

(22) Filed: Mar. 26, 2001

(30) Foreign Application Priority Data
Jun. 19, 2000 (JP) 2000-183551

(51) Int. Cl. H03M 13/03

(52) U.S. Cl. 714/755

(57) ABSTRACT

A decoding unit includes a first decoder and a second decoder. The decoding unit further includes an input/output interface for inputting received code sequences, and channel value memories for storing the received codes sequences. Placing prior values at their initial value of zero, the first decoder decodes a first block, and the second decoder decodes a second block of the received code sequences in parallel. Among the decoded results, that is, posterior values and external values, the external values are stored in an external value memory. In the next decoding, the external values are read as prior values. The decoding process is repeated by a predetermined number of times, and posterior values of the final decoded result is output from the input/output interface as the decoded result. The decoding unit can reduce the time required for decoding because of the parallel decoding of the blocks.

### BACKGROUND OF THE INVENTION

1. Field of the Invention

The present invention relates to a decoding unit and an encoding/decoding unit of a turbo-code sequence, which can correct errors occurring in digital radio communications and digital magnetic recording, for example.

2. Description of Related Art

Recently, turbo-codes draw attention as an error-correcting code that can achieve a low decoding error rate at a low SNR (Signal to Noise Ratio). Here, encoding into a turbo-code will be described, first, followed by a description of decoding the turbo-code.

First, encoding into the turbo-code will be described. FIG. 12A is a block diagram showing a configuration of conventional encoder for encoding to a turbo-code with a coding rate of 1/3 and a constraint length of three. In FIG. 12A, the reference numeral 101A designates a component encoder for generating a first parity bit sequence P1 from an information bit sequence D; and 101B designates another component encoder for generating a second parity bit sequence P2 from an information bit sequence D* generated by rearranging the information bit sequence D by an interleaver 102 that mixes the bits dᵢ of the information bit sequence D according to a prescribed mapping, thereby generating the information bit sequence D*.

In the component encoder 101A or 101A as shown in FIG. 12B, the reference numeral 111 designates an adder for adding an input bit and outputs of delay elements 112 and 113, each of which delays an input bit until the next bit is supplied; and 114 designates an adder for adding the output of the adder 111 and the output of the delay element 113 to output a parity bit.

Next, the operation of the conventional encoder will be described.

FIG. 13 is a state transition diagram of the component encoders 101A and 101B of FIG. 12B, and FIG. 14 is a trellis diagram of the component encoder 101A or 101B of FIG. 12B. In the following description, it is assumed that the bit length of the information bit sequence D is N, where N is a positive integer, and that D is expressed as D={d₀, d₁, . . . , d_{N-2}, d_{N-1}}.

In the initial state, the delay elements 112 and 113 of the component encoders 101A and 101B are placed at their initial value of zero.

Subsequently, the information bit sequence D is supplied to the component encoder 101A and the interleaver 102. The interleaver 102 rearranges the bits of the information bit sequence D, in which case, the N integers 0, . . . , N−1, suffixes of N bits d₀, . . . , d_{N-1}, are rearranged. The mapping of the rearrangement is expressed by “INT” as in Expression (1), and its inverse mapping is expressed by “DEINT” . Accordingly, DEINT(INT(k))=k and INT(DEINT(k))=k hold.

INT:K [symbol] k→INT(k) [symbol] K

DEINT:K [symbol] k→DEINT (k) [symbol] K (1)

The information bit sequence D* (D*={d*ₖ}, where d*ₖ=d_{INT(k)}, k=0, 1, . . . , N−1) generated by the interleaver 102 is supplied to the component encoder 101B.

In the component encoder 101A, receiving information bit dₖ at a point of time k, the adder 111 calculates the exclusive-OR of the information bit dₖ and the bit values held in the delay elements 112 and 113, and supplies its output to the delay element 112 and the adder 114.

Then, the adder 114 calculates the exclusive-OR between the output of the adder 111 and the bit value held in the delay element 113, and outputs the result as the parity bit p1ₖ. Here, the delay element 112 holds the information bit dₖ until the next information bit dₖ₊₁ is input, and then supplies the information bit dₖ to the delay element 113 which holds the one more previous information bit dₖ₋₁ until the information bit dₖ is input.

Likewise, the component encoder 101B receives the information bit d*ₖ at the point of time k, and generates and outputs the parity bit p2ₖ.

Thus, at the point of time k, three bits (dₖ, p1ₖ, p2ₖ), the information bit, first parity bit and second parity bit, are output simultaneously.

The component encoders 101A and 101B make transitions into new states as shown in FIGS. 13 and 14 every time the information bit dₖ is input, and the parity bits p1ₖ and p2ₖ they generate are determined by their states, that is, by the values held in the delay elements 112 and 113, and by the information bits dₖ and d*k supplied to the component encoders 101A and 101B.

In the state transition diagram of FIG. 13, a pair of digits in each circle designate the values held in the delay elements 112 and 113 in the component encoder 101A or 101B. For example, two digits “01” express that the delay element 112 holds “0” and the delay element 113 holds “1”. On the other hand, a pair of digits affixed to each arrow designate the input information bit dₖ and the generated parity bit piₖ (i=1 or 2). For example, the digits “10” express that the information bit dₖ is “1” and the parity bit piₖ is “0”.

The trellis of FIG. 14 shows the state transition of the component encoder 101A or 101B along the time sequence. As shown in FIG. 13, each state at the point of time k can make transition to two states at the next point of time k+1, and from two states at the previous point of time k−1. Accordingly, as shown in FIG. 14, the state of the component encoder 101A or 101B makes transition to one of two states in accordance with the information bit and the values held in the delay elements 112 and 113 every time the information bit is input.

In the turbo-code encoder, the component encoders 101A and 101B complete their transition after encoding the final information bit.

Specifically, after the final information bit d_{N-1} is supplied to the component encoder 101A, two additional information bits (d_{N}, d_{N+1}) are supplied to the component encoder 101A to place its state to “00”, that is, to place the contents of the delay elements 112, and 113 to “0”. The two additional information bits (d_{N}, d_{N+1}) are not effective information. In response to the two additional information bits, the component encoder 101A generates two additional parity bits (P1_{N}, P1_{N+1}).

Likewise, after supplying the component encoder 101B with the final information bit d*_{N-1}=d_{INT(N-1)}, two additional information bits d*_{N} and d*_{N+1} are supplied thereto so that its state is returned to “00”. In response to the two additional information bits, the component encoder 101B generates two additional parity bits P2_{N} and P2_{N+1}.

Thus, the states of the component encoders 101A and 101B are placed at their initial state “00” at the start of encoding the information bit sequence D (point of time k=0), and change their states according to the trellis every time the information bit is input. Then, at the end of the encoding of the information bit sequence D (point of time k=N+2), they are returned to the initial state “00”. The final eight bits d_{N}, d_{N+1}, p1_{N}, p1_{N+1}, d*_{N}, d*_{N+1}, P2_{N} and P2_{N+1} for completing the transition are called tail bits.

As described above, the first and second parity bit sequences P1={p1₀, p1₁, . . . , p1_{N-2}, p1_{N-1}, p1_{N}, p1_{N+1}} and P2={p2₀, p2_{N}, . . . p2_{N1-2}, p2_{N-1}, p2_{N}, p2_{N+1}} are generated from the information bit sequence D={d₀, d₁, . . . , d_{N-2}, d_{N-1}} and the additional information bits {d_{N}, d_{N+1}, d*_{N}, d*_{N+1}}, to output the information bit sequence and additional information bits along with the first and second parity bit sequences. The information bit sequence D′, which is generated by interleaving the information bit sequence D, is not output because it can be produced by rearranging the information bit sequence D.

The information bit sequence and additional information bits in combination with the first and second parity bit sequences constitute the turbo-code to be transmitted via a predetermined channel. or to be recorded on a recording medium. The turbo-code is decoded at a decoding side as a received code sequence after it is received or read out.

In the following description, assume that the received signal of the information bits dₖ (k=0, 1, . . . , N−1) and additional information bits dₖ (k=N, N+1) is xₖ; the received signal of the additional information bits d*ₖ (k=N, N+1) is x*ₖ; the received signal of the first parity bits p1ₖ (k=0, 1, . . . , N+1) is y1ₖ; and the received signal of the second parity bits p2ₖ (k=0, 1, . . . , N+1) is y2ₖ, and that x*ₖ=x_{INT(k)} for k=0, 1, . . . , N−1.

By defining sequences X1, X2, Y1 and Y2 such as x1={xₖ (k=0, 1, . . . , N+1) }, X2={X*ₖ (k=0, 1, . . . , N+1)}, Y1={y1ₖ (k=0, 1, . . . , N+1)} and Y2={y2ₖ (k=0, 1, . . . , N+1)}, the sequences X1 and Y1 are the received sequence corresponding to the component encoder 101A, and the sequences X2 and Y2 are the received sequence corresponding to the component encoder 101B. Let us call the sequence {X1, Y1} a first received code sequence, and the sequence {X2, Y2} a second received code sequence from now on.

Next, the decoding of the turbo-code will be described.

Decording schemes of the turbo-code include SOVA (Soft Output Viterbi Algorithm), MAP (Maximum A Posteriori probability) decoding method, and Log-MAP decoding method, as described in Haruo Ogiwara, “Fundamentals of Turbo-code”, Triceps Publishing, Tokyo, 1999, for example.

Here, the MAP decoding method will be described taking an example of the foregoing turbo-code with the coding rate of 1/3 and the constraint length of three. FIG. 15 is a block diagram showing a configuration of a conventional decoding unit of the turbo-code. In FIG. 15, the reference numeral 201A designates a decoder for generating an external value Le from channel values X1 and Y1 and a prior value La according to the MAP decoding method; 201B designates a decoder for generating an external value Le* and a posterior value L* from the channel value X2 (=X1*) generated by interleaving the channel value X1, the channel value Y2 and the prior value La* according to the MAP decoding method; 202A designates an interleaver for generating prior values La*ₖ by rearranging the bits Leₖ of the external value Le in accordance with a prescribed mapping; 202B designates an interleaver for generating the bit sequence X*={x*ₖ} by rearranging the bits xₖ of the channel value X1 in accordance with a prescribed mapping; 203 designates a deinterleaver for carrying out the inverse mapping of the external values Le*ₖ; and 204 designates a decision circuit for estimating the value of the information bits in accordance with the plus or minus of the posterior values.

Next, the operation of the conventional decoding unit will be described.

FIGS. 16A and 16B are diagrams each showing an example of paths on a trellis of the decoder 201A or 201B of FIG. 15.

First, the decoder 201A calculates the posterior value Lₖ (logarithmic posterior probability ratio) from the channel values X1 and Y1 and the prior value La (La={Laₖ (k=0, 1, . . . , N+1)}) by the following Expression (2). The posterior value Lₖ represents the reliability of the information bit dₖ. It takes an increasing positive value with an increase of the probability of the information bit dₖ being one, and an increasing negative value with an increase of the probability of the information bit dₖ being zero.

$${L}_{k} = L ( {d}_{k} ) = log \frac{P ( {d}_{k} = 1 \vert X1 , Y1 )}{P ( {d}_{k} = 0 \vert X1 , Y1 )} \qquad ( 2 )$$

The calculation of the posterior value Lₖ will be described in detail.

First, the decoder 201A calculates transition probabilities γₖ(m*, m) (m, m*=0, 1, 2, 3) at each point of time k by the following Expression (3). The transition probabilities γₖ(m*, m), which correspond to a branch metric of the Viterbi algorithm, represent the probabilities that the states make a transition from the states m* at the point of time k to the states m at the point of time k+1.

γₖ(m*, m)=P(y1ₖ|p)P(xₖ|i)P(dₖ=i) (3)

where i designates an information bit at the transition, and p designates a parity bit at the transition.

In Expression (3), P(r|b) is a probability of receiving a value r as the received signal when a bit b is transmitted; and P(dₖ=i) is a prior probability of the information bit dₖ being i, which is calculated from the prior value Laₖ by the following Expression (4).

$$P ( {d}_{k} = i ) = \frac{exp ( i \cdot {La}_{k} )}{1 + exp ( {La}_{k} )} \qquad ( 4 )$$

In the first decoding, the prior values Laₖ (k=0, 1, . . . , N−1) are set at zero, whereas the prior values Laₖ (k=N, N+1) of the additional information bits xₖ (k=N, N+1) in the tail bit section are always set at zero.

The transition probabilities γₖ(m*, m) thus calculated are stored in a memory not shown.

Subsequently, the decoder 201A sequentially calculates forward path probabilities αₖ(m) (m=0, 1, 2, 3) from k=0 to k=N+1 using the transition probabilities γₖ(m*, m) (m, m*=0, 1, 2, 3) by the following forward recursive Expression (5), and stores them in the memory not shown. Here, initial values α₀(m) (m=0, 1, 2, 3) of the forward path probabilities are set by Expression (6).

$${α}_{k} ( m ) = {\sum }_{{m}^{*}} {γ}_{k - 1} ( {m}^{*} , m ) {α}_{k - 1} ( {m}^{*} ) \qquad ( 5 )$$

$${α}_{0} ( m ) = \{ \begin{matrix}1 & ( m = 0 ) \\ 0 & ( m \neq 0 )\end{matrix} \qquad ( 6 )$$

Thus, the probabilities αₖ(m) represent probabilities that the states of the encoder make a transition from the initial state m=0 at the point of time k=0 to the states m at the point of time k on the trellis as the time proceeds, which probabilities are successively calculated in the direction of the point of time. In contrast, probabilities βₖ(m), which will be described later, are the probabilities that the states of the encoder reach the states m at the point of time k starting from the final states in the reverse direction of the point of time.

For example, as shown in FIG. 16A, the probabilities αₖ(1) of the path arriving at the state m=1 at the point of time k is calculated from the probabilities αₖ₋₁(0) and αₖ₋₁(2) of the paths in the states m=0 and m=2 at the point of time k−1 according to the following Expression (7).

αₖ(1)=γₖ₋₁(0 1)αₖ₋₁(0)+γₖ₋₁(2, 1)αₖ₋₁(2) (7)

Thus, the decoder 201A calculates the probabilities αₖ(m) of all the forward paths. Subsequently, it calculates the probabilities βₖ(m) (m=0, 1, 2, 3) of the reverse paths by the following reverse recursive Expression (8).

$${β}_{k} ( m ) = {\sum }_{{m}^{*}} {γ}_{k} ( m , {m}^{*} ) {β}_{k + 1} ( {m}^{*} ) \qquad ( 8 )$$

To achieve this, the decoder 201A reads out the transition probabilities γₖ(m, m*) from the memory, calculates the reverse path probabilities βₖ(m) from k=N+1 to k by Expression (8), and stores them in the memory. The reverse path initial values β_{N+}2(m) (m=0, 1, 2, 3) are set according to the following Expression (9).

$${β}_{N + 2} ( m ) = \{ \begin{matrix}1 & ( m = 0 ) \\ 0 & ( m \neq 0 )\end{matrix} \qquad ( 9 )$$

For example, as shown in FIG. 16B, the probability βₖ(2) of the paths arriving at the state m=2 at the point of time k is calculated from the probability βₖ₊₁(0) of the path in the state m=0 at the point of time k+1 and the probability βₖ₊₁(1) of the path in the state m=1 at the point of time k+1 according to the following Expression (10).

βₖ(2)=γₖ(2, 0)βₖ₊₁(0)+γₖ(2, 1)βₖ₊₁(1) (10)

Subsequently, the decoder 201A calculates the posterior value Lₖ in parallel with the calculation of the reverse path probabilities βₖ(m) according to the following Expression (11).

$${L}_{k} = log \frac{{\sum }_{m \to {m}^{*} : {d}_{k} = 1} {α}_{k} ( m ) {γ}_{k} ( m , {m}^{*} ) {β}_{k + 1} ( {m}^{*} )}{{\sum }_{m \to {m}^{*} : {d}_{k} = 0} {α}_{k} ( m ) {γ}_{k} ( m , {m}^{*} ) {β}_{k + 1} ( {m}^{*} )} \qquad ( 11 )$$

In the course of this, the decoder 201A reads out of the memory the reverse path probabilities βₖ₊₁(m*), the transition probabilities γₖ(m, m*) and the forward path probabilities αₖ(m), and calculates the posterior value Lₖ of Expression (2) by Expression (11). The denominator of Expression (11) is the sum total of all the state transitions m→m* when the information bit dₖ is zero, whereas its numerator is the sum total of all the state transitions m→m* when the information bit dₖ is one.

The posterior value Lₖ of Expression (11) is resolved into three terms as in the following Expression (12). The first term LC·Xₖis a value obtained from the channel value xₖ, where Le is a constant depending on the channel (the value Lc·xₖ is called a channel value from now on for the sake of simplicity). The second term Laₖ is a prior value used for calculating the transition probabilities γₖ(m, m*), and the third term Leₖ is an external value indicating an increase of the posterior value due to code constraint.

$$\begin{matrix}{L}_{k} = log \frac{P ( {x}_{k} \vert {d}_{k} = 1 )}{P ( {x}_{k} \vert {d}_{k} = 0 )} + log \frac{P ( {d}_{k} = 1 )}{P ( {d}_{k} = 0 )} + \\ log \frac{{\sum }_{m \to {m}^{*} : {d}_{k} = 1} {α}_{k - 1} ( m ) P ( {y}_{k} \vert p ) {β}_{k} ( {m}^{*} )}{{\sum }_{m \to {m}^{*} : {d}_{k} = 0} {α}_{k - 1} ( m ) P ( {y}_{k} \vert p ) {β}_{k} ( {m}^{*} )} \\ = Lc \cdot {x}_{k} + {La}_{k} + {Le}_{k}\end{matrix} \qquad ( 12 )$$

The decoder 201A further calculates the external value Leₖ by the following Expression (13), and stores it in the memory not shown.

Leₖ=Lₖ−Lc·xₖ−Laₖ (13)

In this way, the decoder 201A calculates the external value Le={Le₀, Le₁, . . . LeN_{N-2}, Le_{N-1}} and supplies it to the interleaver 202A.

The interleaver 202A rearranges the order of the elements of the external value Le to generate the prior value La*={La*ₖ=Le_{INT(k)} (k=0, 1, . . . , N−1)} used by the decoder 201B.

The decoder 201B calculates the posterior value L*ₖ and the external value Le*={Le*₀, Le*₁, . . . , Le_{N-2}, Le_{N-}1} from the channel values X2 and Y2 and the prior value La* in the same manner as the decoder 201A does. The external value Le* is supplied to the deinterleaver 203.

The deinterleaver 203 rearranges the external value Le* according to the prescribed inverse mapping to generate the prior value La={Laₖ−Le*_{DEINT(k)}} to be used by the decoder 201A.

Through the foregoing process, the first decoding of the turbo-code is completed.

The turbo-code decoding unit repeats the foregoing process by a plurality of times to improve the accuracy of the posterior values, and supplies the decision circuit 204 with the posterior values L*ₖ calculated by the decoder 201B at the final stage. The decision circuit 204 decides the values of the information bits dₖ by the plus or minus of the posterior values L*ₖ according to the following Expression (14).

$${d}_{k}^{*} = \{ \begin{matrix}0 & ( {L}_{k}^{*} \leq 0 ) \\ 1 & ( {L}_{k}^{*} > 0 )\end{matrix} \qquad ( 14 )$$

FIG. 17 is a timing chart illustrating the decoding process of the first and second received code sequences by the conventional decoding unit.

As described above, the decoder 201A successively calculates the transition probabilities of the first received code sequence from k=0 to k=N+1 for respective points of time in parallel with the calculation of the forward path probabilities αₖ(m) (step 1), and then the reverse path probabilities βₖ(m) from k=N+2 to k=1 for the respective points of time in parallel with the calculation of the posterior values Lₖ and the external values Leₖ(step 2), thereby completing the first decoding of the received code sequence. After that, the decoder 201B carries out similar processing for the second received code sequence (steps 3 and 4) to calculate the posterior values L*ₖ and the external values Le*ₖ.

Thus, the first decoding of the turbo-code is completed. As illustrated in FIG. 17, the number of steps taken by the single decoding is 4N, where N is the code length of the turbo-code.

With the foregoing configuration, the conventional decoder or decoding method has a problem of making it difficult to implement the real time decoding, and to reduce the time required for the decoding. This is because the conventional decoder must wait until all the received sequences and external values are prepared because they must be interleaved or deinterleaved.

In addition, the conventional decoder or decoding method has a problem of making it difficult to reduce the time required for the decoding. This is because an increase of the code length prolongs the decoding because the number of steps is proportional to the code length.

Moreover, the conventional turbo-code decoding has a problem of making it difficult to reduce the capacity of the memory and the circuit scale when the code length or the constraint length is large (when the component encoders have a large number of states). This is because it must comprise a memory with a capacity proportional to the code length to store the calculated forward path probabilities.

### SUMMARY OF THE INVENTION

The present invention is implemented to solve the foregoing problems. It is therefore an object of the present invention to provide a decoding unit capable of reducing the decoding time by a factor of n, by dividing received code sequences into n blocks along the time axis and by decoding these blocks in parallel.

Another object of the present invention is to provide a decoding unit capable of reducing the capacity of the path metric memory for storing forward path probabilities by a factor of nearly n by dividing received code sequences into n blocks along the time axis, and by decoding them in sequence.

According to a first aspect of the present invention, there is provided a decoding unit for decoding a turbo-code sequence, the decoding unit comprising: a plurality of decoders for dividing a received code sequence into a plurality of blocks along a time axis, and for decoding at least two of the blocks in parallel.

Here, the received code sequence may consist of a first received code sequence and a second received code sequence, wherein the first received code sequence may consist of a received sequence of an information bit sequence and a received sequence of a first parity bit sequence generated from the information bit sequence, and the second received code sequence may consist of a bit sequence generated by interleaving the received sequence of the information bit sequence, and a received sequence of a second parity bit sequence generated from a bit sequence generated by interleaving the information bit sequence, and wherein the decoding unit may comprise a channel value memory for storing the first received code sequence and the received sequence of the second parity bit sequence.

The plurality of decoders may comprise at least a first decoder and a second decoder, each of which may comprise a channel value memory interface including an interleave table for reading each of the plurality of blocks of the first and second received code sequence from the channel value memory.

Each of the plurality of decoders may comprise: a transition probability calculating circuit for calculating forward and reverse transition probabilities from channel values and prior values of each of the blocks; a path probability calculating circuit for calculating forward path probabilities from the forward transition probabilities, and reverse path probabilities from the reverse transition probabilities; a posterior value calculating circuit for calculating posterior values from the forward path probabilities, the reverse transition probabilities and the reverse path probabilities; and an external value calculating circuit for calculating external values for respective information bits by subtracting from the posterior values the channel values and the prior values corresponding to the information bits.

Each of the plurality of decoders may further comprise: means for supplying another of the decoders with one set of the forward path probabilities and the reverse path probabilities calculated finally; and an initial value setting circuit for setting the path probabilities supplied from another decoder as initial values of the path probabilities.

The first parity bit sequence and the second parity bit sequence may be punctured before transmitted, and each of the decoders may comprise a depuncturing circuit for inserting a value of least reliability in place of channel values corresponding to punctured bits of the received code sequences.

Every time input of one of the blocks has been completed, each of the decoders may start decoding of the block, and output posterior values corresponding to the channel values of the block as posterior values corresponding to the information bits of the block.

At least one of the plurality of decoders may decode one of the blocks whose input has not yet been completed to generate posterior values of the block, and use values corresponding to the posterior values as prior values of the block whose input has been completed.

According to a second aspect of the present invention, there is provide a decoding unit for decoding a turbo-code sequence, the decoding unit comprising: a decoder for dividing a received code sequence into a plurality of blocks along a time axis, and for decoding each of the blocks in sequence.

Here, the decoding unit may further comprise a channel value memory for storing the received code sequence, wherein the decoder may comprise: a channel value memory interface for reading the received code sequence from the channel value memory block by block; a transition probability calculating circuit for calculating forward and reverse transition probabilities from channel values and prior values of each of the blocks; a path probability calculating circuit for calculating forward path probabilities from the forward transition probabilities, and reverse path probabilities from the reverse transition probabilities; a posterior value calculating circuit for calculating posterior values from the forward path probabilities, the reverse transition probabilities and the reverse path probabilities; and an external value calculating circuit for calculating external values for respective information bits by subtracting from the posterior values the channel values and the prior values corresponding to the information bits.

Any adjacent blocks may overlap each other by a predetermined length.

According to a third aspect of the present invention, there is provided an encoding/decoding unit including an encoding unit for generating a turbo-code sequence from an information bit sequence, and a decoding unit for decoding a turbo-code sequence, the encoding unit comprising: a first component encoder for generating a first parity bit sequence from the information bit sequence; an interleaver for interleaving the information bit sequence; a second component encoder for generating a second parity bit sequence from an interleaved information bit sequence output from the interleaver; and an output circuit for outputting the information bit sequence and the outputs of the first and second component encoders, and the decoding unit comprising: a plurality of decoders for dividing a first received code sequence and a second received code sequence into a plurality of blocks along a time axis, and for decoding at least two of the blocks in parallel, wherein the first received code sequence consists of a received sequence of the information bit sequence and a received sequence of the first parity bit sequence, and the second received code sequence consists of a bit sequence generated by interleaving the received sequence of the information bit sequence, and*a received sequence of the second parity bit sequence; and a channel value memory for storing the first received code sequence and the received sequence of the second parity bit sequence.

### BRIEF DESCRIPTION OF THE DRAWINGS

FIG. 1 is a block diagram showing a configuration of a decoding unit of an embodiment 1 in accordance with the present invention;

FIG. 2 is a block diagram showing a configuration of a decoder of FIG. 1;

FIG. 3 is a flowchart illustrating the operation of the decoding unit of the embodiment 1;

FIG. 4 is a timing chart illustrating the operation of the decoding unit of the embodiment 1;

FIG. 5 is a block diagram showing a configuration of an encoder unit of an embodiment 2 in accordance with the present invention;

FIG. 6 is a block diagram showing a configuration of a decoding unit of the embodiment 2;

FIG. 7 is a block diagram showing a configuration of a decoder as shown in FIG. 6;

FIGS. 8A and 8B are timing charts illustrating input states of received sequences X, Y1 and Y2 to the decoding unit of an embodiment 3 in accordance with the present invention;

FIG. 9 is a flowchart illustrating the operation of the decoding unit of the embodiment 3;

FIG. 10 is a block diagram showing a configuration of a decoder unit of an embodiment 4 in accordance with the present invention;

FIG. 11 is a diagram illustrating correspondence between a first received code sequence and its blocks;

FIG. 12A is a block diagram showing a configuration of a conventional encoder for generating a turbo-code sequence with a coding rate of 1/3 and a constraint length of three;

FIG. 12B is a block diagram showing a configuration of a component encoder of FIG. 12A;

FIG. 13 is a state transition diagram of the component encoder of FIG. 12B;

FIG. 14 is a trellis diagram of the component encoder of FIG. 12B;

FIG. 15 is a block diagram showing a configuration of a conventional decoding unit of the turbo-code;

FIGS. 16A and 16B are trellis diagrams illustrating examples of paths on the trellis of a decoder of FIG. 15; and

FIG. 17 is a timing chart illustrating the decoding operation of the first and second received code sequences by the conventional decoding unit.

### DETAILED DESCRIPTION OF THE PREFERRED EMBODIMENTS

The invention will now be described with reference to the accompanying drawings.

### EMBODIMENT 1

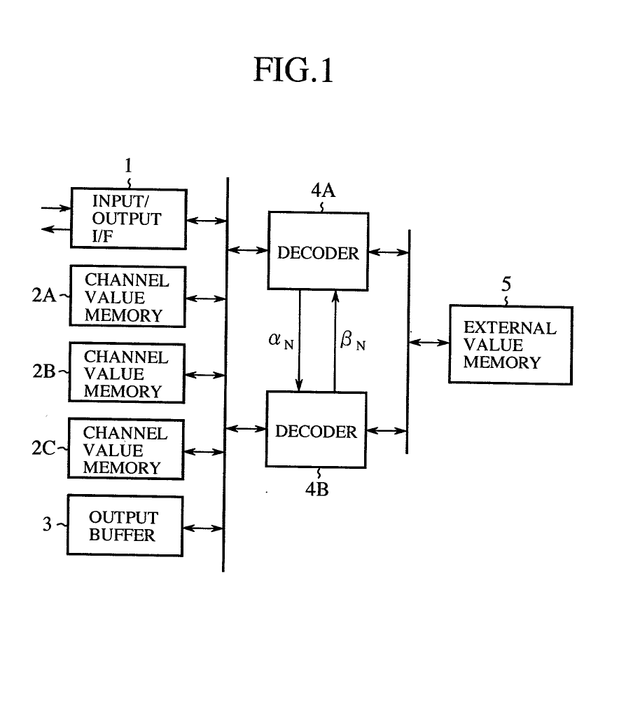

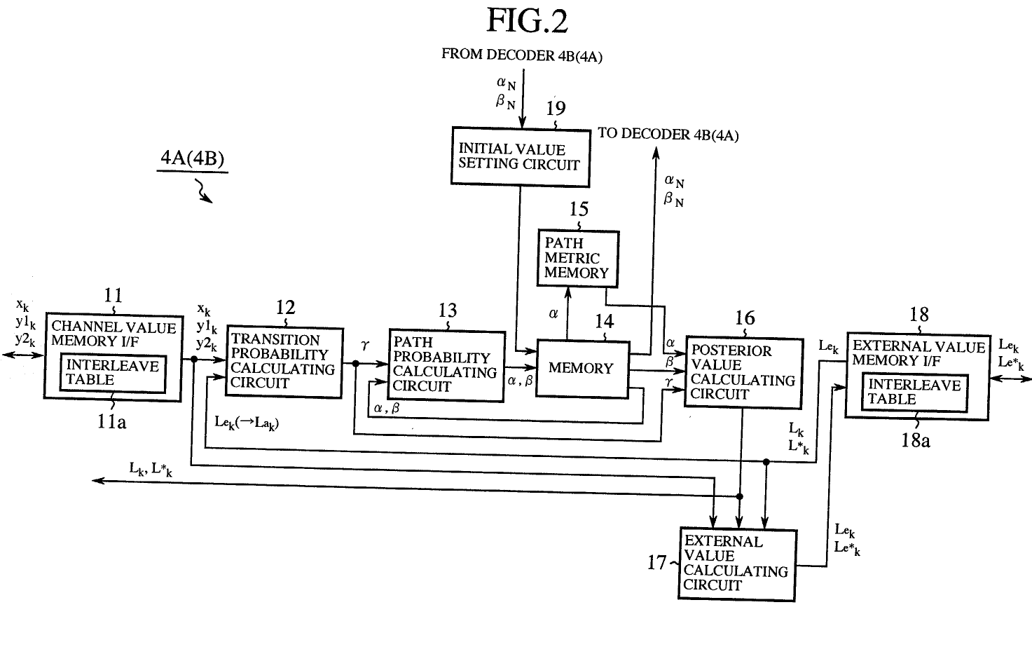

FIG. 1 is a block diagram showing a configuration of a decoding unit of an, embodiment 1 in accordance with the present invention; and FIG. 2 is a block diagram showing a configuration of a decoder of FIG. 1.

In FIG. 1, the reference numeral 1 designates an input/output interface for inputting channel values received as received code sequences, and for outputting a decoded result; reference numerals 2A, 2B and 2C each designate a channel value memory for storing channel values captured through the input/output interface 1; the reference numeral 3 designates an output buffer for storing decoded results of individual blocks of a turbo-code output from the decoders 4A and 4B; reference numerals 4A and 4B each designate a decoder for carrying out soft input/soft output decoding of the blocks constituting the turbo-code, and the reference numeral 5 designates an external value memory for storing the external values calculated by the soft input/soft output decoding of the turbo-code.

In the decoder 4A or 4B as shown in FIG. 2, the reference numeral 11 designates a channel value memory interface for reading the channel values from the channel value memories 2A, 2B and 2C; 12 designates a transition probability calculating circuit for calculating transition probabilities from the channel values and external values; 13 designates a path probability calculating circuit for calculating forward path probabilities from the transition probabilities according to the forward recursive expression, and for calculating reverse path probabilities according to reverse recursive expression; 14 designates a memory circuit for temporarily storing the forward and reverse path probabilities; 15 designates a path metric memory for storing the forward path probabilities; 16 designates a posterior value calculating circuit for calculating posterior values from the forward and reverse path probabilities and the transition probabilities; 17 designates an external value calculating circuit for calculating external values from the posterior values; 18 designates an external value memory interface for exchanging the external values with the external value memory 5; and 19 designates an initial value setting circuit for setting initial values of the path probabilities in the memory circuit 14. The channel value memory interface 11 and the external value memory interface 18 have interleave tables 11a and 18a, respectively.

The channel value memories 2A, 2B and 2C and output buffer 3 each consist of a multi-port memory with two input/output ports, and the external value memory 5 is a multi-port memory with four input/output ports enabling simultaneous reading through two ports and writing through another two ports.

Next, the operation of the present embodiment 1 will be described.

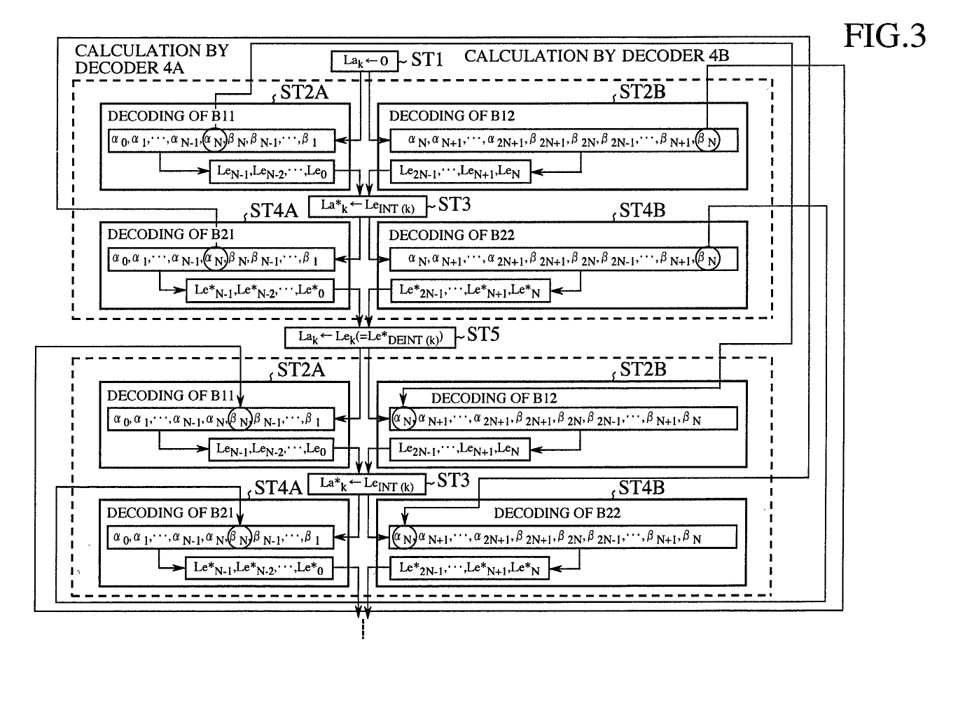

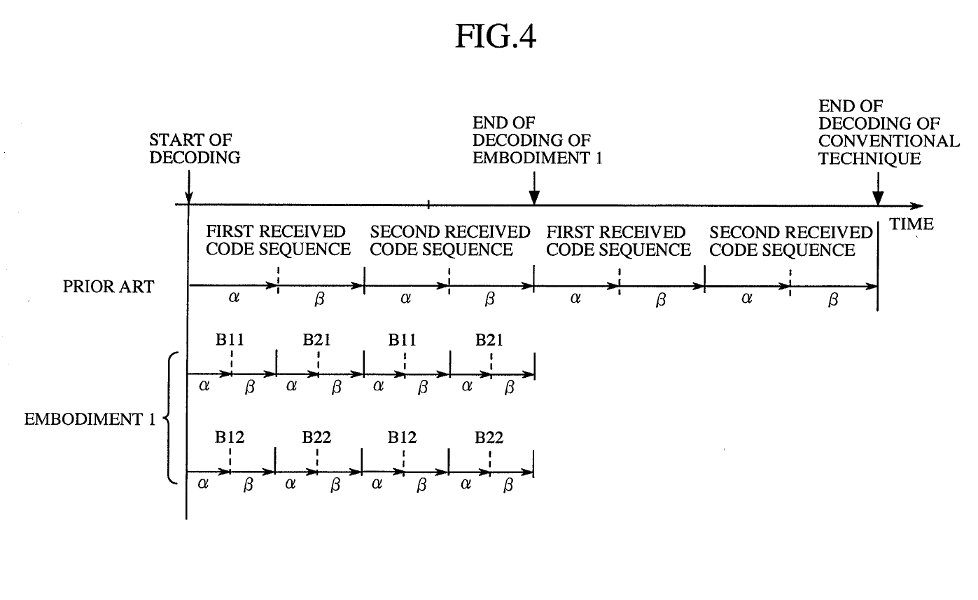

FIG. 3 is a flowchart illustrating the operation of the decoding unit of the embodiment 1; and FIG. 4 is a timing chart illustrating the operation of the decoding unit of the embodiment 1.

Here, the operation will be described with regard to the turbo-code with a coding rate of 1/3 and a constraint length of three. In the present embodiment 1, although the information bit length is assumed to be 2N for the sake of simplicity, it is obvious that other turbo-codes with different coding rates or constraint lengths are also decodable. The symbols designates the same items as described before.

First, receiving a received sequence X={x₀, x₁, . . . , x_{2N-1}, x_{2N}, x_{2N+1}x*_{2N}, x_{2N+1}} of the information bit sequence (including 4-bit additional information), a received sequence Y1={y1₀, y1₁, . . . , y1_{2N-1}, y1_{2N}, y1_{2N+1}} of the first-parity bit sequence P1, and a received sequence Y2={y2₀, y₁, . . . , y2_{2N-1}, y2_{2N}, y2_{2N+1}} of the second parity bit sequence P2, the input/output interface 1 stores the received sequences X, Y1 and Y2 into the channel value memories 2A, 2B and 2C, respectively.

In this case, it stores the values xₖ (k=0, 1, . . . , 2N+1) at addresses k of the channel value memory 2A, and the values x*_{2N} and x*_{2N+}1 at addresses 2N+2 and 2N+3 of the channel value memory 2A. Likewise, it stores the values y1ₖ (k=0, 1, . . . , 2N+1) at addresses k of the channel value memory 2B, and the values y2ₖ (k=0, 1, . . . , 2N+1) at addresses k of the channel value memory 2C.

Here, the sequences X1 and X2 are defined as follows from the received code sequence X.

X1={xₖ(k=0, 1, . . . , 2N+1)}

X2={xₖ=x_{INT(k)}(k=0, 1, . . . , 2N−1), x*_{2N}, x*_{2N+1}}

Thus, the sequences X1 and Y1 constitute the received sequence corresponding to the information bit sequence and parity bit sequence of the first component encoder of the turbo-code sequence, and the sequences X2 and Y2 constitute the received sequence corresponding to the information bit sequence and parity bit sequence of the second component encoder of the turbo-code sequence. In the following description, the sequence {X1, Y1} is referred to as a first received code sequence, and the sequence {X2, Y2} is referred to as a second received code sequence.

Here, sub-sequences X11, X12, X21, X22, Y11, Y12, Y21 and Y22 that are formed by halving the sequences X1, X2, Y1 and Y2, are defined as follows:

X11={xₖ (k=0, 1, . . . , N−1)}

X12={xₖ (k=N, N+1, . . . , 2N+1)}

X21={x*ₖ (k=0, 1, . . . , N−1)}

X22={x*ₖ (k=N, N+1, . . . , 2N+1)}

Y11={y1ₖ (k=0, 1, . . . , N−1)}

Y12={y1ₖ (k=N, N+1, . . . , 2N+1)}

Y21={y2ₖ (k=0, 1, . . . , N−1)}

Y22={y2ₖ (k=N, N+1, . , 2N+1)}

According to the sub-sequences, the first received code sequence {X1, Y1} consists of a first block B11={X11, Y11} and a second block B12={X12, Y12}, and the second received code sequence {X2, Y2} consists of a first block B21={X21, Y21} and a second block B22={X22, Y22}.

The decoders 4A and 4B each place the prior values Laₖ at their initial value zero at step ST1 to decode the first received code sequence, first. Subsequently, the decoder 4A reads the channel values constituting the first block B11 of the first received code sequence from the channel value memories 2A and 2B at step ST2A, and decodes the first block B11 of the first received code sequence. In parallel with this, as shown in FIG. 4, the decoder 4B reads the channel values constituting the second block B12 of the first received code sequence from the channel value memories 2A and 2B at step ST2B, and decodes the second block B12 of the first received code sequence.

Specifically, from the first block B11={X11, Y11} of the first received code sequence, the decoder 4A calculates the forward path probabilities αₖ (k=0, 1, . . . , N) according to the forward recursive expression, and then the reverse path probabilities βₖ (k=N, N−1, . . . , 1) according to the reverse recursive expression. Subsequently, the decoder 4A calculates the posterior values Lₖ (k=0, 1, . . . , N−1) from the forward path probabilities α*ₖ and the reverse path probabilities βₖ, and then calculates the external values Leₖ (k=0, 1, . . . , N−1) of the first half bits dₖ of the information bit sequence.

In parallel with this, from the second block B12={X12, Y12} of the first received code sequence, the decoder 4B calculates the forward path probabilities αₖ (k=N, N+1, . . . , 2N+1) according to the forward recursive expression, and then the reverse path probabilities βₖ (k=2N+1, 2N, . . . , N) according to the reverse recursive expression. Subsequently, the decoder 4B calculates the posterior values Lₖ (k=N, N+1, . . . , 2N−1) from the forward path probabilities αₖ and the reverse path probabilities βₖ, and then calculates the external values Leₖ (k=N, N+1, . . . , 2N−1) of the second half bits dₖ of the information bit sequence.

Although the second block B12 of the first received code sequence includes the additional information bits of the tail bits, the posterior values and external values of the additional information bits are not calculated.

Thus, the decoders 4A and 4B operate in parallel to perform the MAP decoding of the first received code sequence {X1, Y1}.

Then, at step ST3, the decoders 4A and 4B each generates the prior values L*aₖ for decoding the second received code sequence by interleaving the external values Leₖ. Subsequently, at step ST4A, the decoder 4A reads the channel values constituting the first block B21 of the second received code sequence from the channel value memories 2A and 2C, and decodes the first block B21. In parallel with this, at step ST4B as shown in FIG. 4, the decoder 4B reads the channel values constituting the second block B22 of the second received code sequence from the channel value memories 2A and 2C, and decodes the second block B22. Thus, they generate the posterior values Lₖ and stores them into the output buffer 3, and then generate the external values Le*ₖ and stores them into the external value memory 5.

Specifically, from the first block B21={X21, Y21} of the second received code sequence, the decoder 4A calculates the forward path probabilities αₖ (k=0, 1, . . . , N) according to the forward recursive expression, and then the reverse path probabilities βₖ (k=N, N−1, . . . , 1) according to the reverse recursive expression. Subsequently, the decoder 4A calculates the posterior values Lₖ (k=0, 1, ... N−1) from the forward path probabilities αₖand the reverse path probabilities βₖ, and then calculates the external value Le*ₖ (k=0, 1, . . . , N−1) of the first half bits d*ₖ of the interleaved information bit sequence.

In parallel with this, from the second block B22={X22, Y22} of the second received code sequence, the decoder 4B calculates the forward path probabilities αₖ(k=N, N+1, . . . , 2N+1) according to the forward recursive expression, and then the reverse path probabilities βₖ (k=2N+1, 2N, . . . , N) according to the reverse recursive expression. Subsequently, the decoder 4B calculates the posterior values Lₖ (k=N, N+1, . . . , 2N−1) from the forward path probabilities αₖ and the reverse path probabilities βₖ, and then calculates the external value Le*ₖ (k=N, N+1, . . . , 2N−1) of the second half bits d*ₖ Of the interleaved information bit sequence.

Although the second block B22 of the second received code sequence includes the additional information bits of the tail bits, the posterior values and external values of the additional information bits are not calculated.

Thus, the decoders 4A and 4B operate in parallel to perform the MAP decoding of the second received code sequence {X2, Y2}.

After that, at step ST5, the decoders 4A and 4B deinterleave the external values Le*ₖ to generate the prior values Laₖ for the decoding. Here, the deinterleaving is not required when the external values Le*ₖ are stored in addresses INT(k) of the external value memory 5, and the posterior values Leₖ are read from the addresses k as the prior values Laₖ in the next decoding.

Thus, the first decoding of the turbo-code is completed. As shown in FIG. 3, in the second and the following decoding, the external values Leₖ generated by the previous decoding are used as the prior values Laₖ to carry out the decoding by the number of times required, and the posterior values generated in the final decoding are output. Then, the values of the information bits are estimated from the posterior values.

Next, the operation of the decoders 4A and 4B will be described in more detail with reference to FIG. 2.

First, the operation of the decoder 4A to decode the first block B11 of the first received code sequence (step ST2A) will be described.

Before starting the calculation of the forward path probabilities αₖ(m), the initial value setting circuit 19 in the decoder 4A sets their initial values at α₀(0)=1 and α₀(m)=0 (m=1, 2, 3) in the memory circuit 14.

Subsequently, step by step from k=0 to k=N−1, the transition probability calculating circuit 12 captures the value xₖ stored at the address k of the channel value memory 2A and the y1ₖ stored in the channel value memory 2B via the channel value memory interface 11, along with the external value Leₖ stored in the address k of the external value memory 5 via the external value memory interface 18.

The transition probability calculating circuit 12 uses the external value Leₖ as the prior value Laₖ, calculates the transition probability γₖ (m*, m) of each forward state transition from the prior value Laₖ and channel values xₖ and y1ₖ by the foregoing Expressions (3) and (4), and supplies the transition probabilities γₖ(m*,m) thus obtained to the path probability calculating circuit 13. In the first decoding, instead of reading the external values Leₖ, the prior values Laₖ are set at zero (step ST1).

The path probability calculating circuit 13 calculates the forward path probabilities αₖ(m) (m=0, 1, 2, 3) at the point of time k from the transition probabilities yₖ₋₁(m*, m) and the previous forward path probabilities αₖ₋₁(m*) (m*=0, 1, 2, 3) stored in the memory circuit 14 by the foregoing Expression (5), and stores them into the memory circuit 14.

The memory circuit 14 delays the forward path probabilities αₖ(m) calculated by the path probability calculating circuit 13 by the period of the points of time (that is, the interval between two adjacent points of time), and supplies them to the path probability calculating circuit 13 and the path metric memory 15 to be stored at its addresses k.

Subsequently, after calculating the final forward path probabilities α_{N}(m) (m=0, 1, 2, 3), the path probability calculating circuit 13 successively calculates the reverse path probabilities βₖ(m) from k=N−1 to k=1. The final forward path probabilities α_{N}(m) (m=0, 1, 2, 3) are also supplied to the initial value setting circuit 19 of the decoder 4B to be stored.

In this case, before starting the calculation of the reverse path probabilities βₖ(m), the initial value setting circuit 19 sets in the memory circuit 14 their initial values at β_{N}(m)=¼ (m=0, 1, 2, 3) in the first decoding, and at β_{N}(m) (m=0, 1, 2, 3), which are calculated in the previous decoding of the second block B12 of the first received code sequence, in the second and the following decoding.

In the calculation of the reverse path probabilities βₖ(m), the transition probability calculating circuit 12 captures the channel value xₖstored in the channel value memory 2A and the channel value y1ₖ stored in the channel value memory 2B via the channel value memory interface 11, along with the external value Leₖ stored in the address k of the external value memory 5 via the external value memory interface 18.

The transition probability calculating circuit 12 uses the external value Leₖ as the prior value Laₖ, calculates the transition probability γₖ(m*, m) of each forward state transition from the prior value Laₖ and channel values xₖ and y1ₖ by Expressions (3) and (4), and supplies the resultant transition probabilities γₖ(m*, m) to the path probability calculating circuit 13 and the posterior value calculating circuit 16. In the first decoding, instead of reading the external values Leₖ, the prior values Laₖ are set at zero (step ST1)

The path probability calculating circuit 13 calculates the reverse path probabilities βₖ(m) (m=0, 1, 2, 3) at the point of time k from the transition probabilities γₖ(m*, m) and the subsequent reverse path probabilities βₖ₊1(m*) (m*=0, 1, 2, 3) stored in the memory circuit 14 by the foregoing Expression (8), and stores them into the memory circuit 14.

The memory circuit 14 delays the reverse path probabilities βₖ(m) calculated by the path probability calculating circuit 13 by the period of the points of time, and supplies them to the path probability calculating circuit 13 and the posterior value calculating circuit 16.

Thus, at the point of time k, the posterior value calculating circuit 16 is supplied with the reverse path probabilities βₖ₊₁(m) from the memory circuit 14, the transition probabilities γₖ(m, m*) from the transition probability calculating circuit 12, and the forward path probabilities αₖ(m) (m 0, 1, 2, 3) stored at the address k of the path metric memory 15. Incidentally, the reverse path probabilities βₖ(m) are successively calculated from k=N−1 to k=1.

The posterior value calculating circuit 16 calculates the posterior values Lₖ from these forward path probabilities αₖ(m) (m=0, 1, 2, 3), the reverse path probabilities βₖ₊₁(m*) (m=0, 1, 2, 3) and the transition probabilities γₖ(m, m*) (m, m*) =0, 1, 2, 3) by the foregoing Expression (11), and supplies them to the external value calculating circuit 17.

The external value calculating circuit 17 calculates each external value Leₖ by subtracting the channel value Lc·xₖ and prior value Laₖ from the posterior value Lₖ, and writes the resultant external values to the addresses k of the external value memory 5 via the external value memory interface 18.

In this way, the decoder 4A decodes the first block B11 of the first received code sequence, thereby generating the external values Leₖ (k=0, 1, . . . , N−1).

Next, the operation of the decoder 4B to decode the second block B12 of the first received code sequence (step ST2B) will be described. Just as the decoder 4A that decodes the first block B11, the decoder 4B carries out the MAP decoding of the second block B12={X112, Y12} of the first received code sequence by placing the prior values Laₖ at zero.

First, the initial value setting circuit 19 sets in the memory circuit 14 the initial values of the forward path probabilities at α_{N}(m)=¼ (m=0, 1, 2, 3) in the first decoding, and at α_{N}(m) (m=0, 1, 2, 3), which are calculated in the previous decoding of the first block B11 of the first received code sequence, in the second and subsequent decoding.

Subsequently, the transition probability calculating circuit 12 successively captures the channel values xₖ and y1ₖ from k=N to k=2N+1, and the external values Leₖ from k=N to k=2N−1.

The transition probability calculating circuit 12 uses the external values Leₖ as the prior values Laₖ, calculates the transition probabilities γₖ(m*, m) of individual forward state transitions from the prior values Laₖ and channel values xₖ and y1ₖ by the foregoing Expressions (3) and (4), and supplies them to the path probability calculating circuit 13. In the first decoding, instead of reading the external values Leₖ, the prior values Laₖ are set at zero (step ST1). In contrast, the prior values of the additional information bits are always placed at zero.

The path probability calculating circuit 13 calculates the forward path probabilities αₖ(m) (m=0, 1, 2, 3) at the point of time k from the transition probabilities γₖ₋₁(m*, m) and the previous forward path probabilities αₖ₋₁(m*) (m=0, 1, 2, 3) stored in the memory circuit 14 by the forward recursive Expression (5), and stores them into the memory circuit 14.

The memory circuit 14 delays the forward path probabilities αₖ(m) calculated by the path probability calculating circuit 13 by the period of the points of time, and supplies them to the path probability calculating circuit 13 and the path metric memory 15 to be stored at its addresses k.

Subsequently, after calculating the final forward path probabilities α_{2N+1}(m), the path probability calculating circuit 13 successively calculates the reverse path probabilities βₖ(m) from k=2N+1 to k=N. The final reverse path probabilities β_{N}(m) are also supplied to the initial value setting circuit 19 of the decoder 4A to be stored.

In this case, before starting the calculation of the reverse path probabilities βₖ(m), the initial value setting circuit 19 sets their initial values at β_{2N+2}(0)=1 and β_{2N+2}(m)=0 (m=1, 2, 3) in the memory circuit 14.

In the calculation of the reverse path probabilities βₖ(m), the transition probability calculating circuit 12 captures the channel values xₖ stored in the channel value memory 2A and the channel values y1ₖ stored in the channel value memory 2B via the channel value memory interface 11, along with the external values Leₖ stored in the addresses k of the external value memory 5 via the external value memory interface 18.

The transition probability calculating circuit 12 uses the external values Leₖ as the prior values Laₖ, calculates the transition probabilities γₖ(m, m*) of individual reverse state transitions from the prior values Laₖ and channel values xₖ and y1ₖ by the foregoing Expressions (3) and (4), and supplies them to the path probability calculating circuit 13 and the posterior value calculating circuit 16. In the first decoding, instead of reading the external value Leₖ, the prior values Laₖ are set at zero (step ST1).

The path probability calculating circuit 13 calculates the reverse path probabilities βₖ(m) at each point of time k from the transition probabilities γₖ(m, m) and the subsequent reverse path probabilities βₖ₊₁(m*) stored in the memory circuit 14 by the reverse recursive Expression (8), and stores them into the memory circuit 14.

The memory circuit 14 delays the reverse path probabilities βₖ(m) calculated by the path probability calculating circuit 13 by the period of the points of time, and supplies them to the path probability calculating circuit 13 and the posterior value calculating circuit 16.

Thus, at the point of time k, the posterior value calculating circuit 16 is supplied with the reverse path probabilities βₖ₊₁(m) from the memory circuit 14, the transition probabilities γₖ(m, m*) from the transition probability calculating circuit 12, and the forward path probabilities αₖ(m) stored at the address k of the path metric memory 15. The reverse path probabilities βₖ(m) are successively calculated from k=2N+1 to k=N.

The posterior value calculating circuit 16 calculates the posterior values Lₖ from these forward path probabilities αₖ(m), the reverse path probabilities βₖ₊₁(m*) and the transition probabilities γₖ(m, m*) (m, m*=0, 1, 2, 3) by Expression (11), and supplies them to the external value calculating circuit 17.

The external value calculating circuit 17 calculates each external value Leₖ by subtracting the channel value Lc·xₖ and prior value Laₖ from the posterior value Lₖ, and writes the resultant external values to the addresses k of the external value memory 5 via the external value memory interface 18.

In this way, the decoder 4B decodes the second block B12 of the first received code sequence, thereby generating the external values Leₖ (k=N, N+1, . . . , 2N−1). Here, the external values of the additional information bits are not calculated.

At this stage, the external value memory 5 stores the external values Leₖ (k=0, 1, . . . , 2N−1) that are generated by the MAP decoding of the first received code sequence {X1, Y1}.

Next, the operation of the decoder 4A to decode the first block B21 of the second received code sequence (step ST4A) will be described. The decoder 4A uses the interleaved values of the external values Leₖ generated from the first received code sequence as the prior values La*ₖ, and carries out the MAP decoding of the first block B21={X21, Y21} of the second received code sequence in the same manner as it decodes the first block B11 of the first received code sequence.

Before starting the calculation of the forward path probabilities αₖ(m), the initial value setting circuit 19 in the decoder 4A sets their initial values at α₀(0)=1 and α₀(m)=0 (m=1, 2, 3) in the memory circuit 14.

Subsequently, step by step from k=0 to k=N−1, the transition probability calculating circuit 12 captures the value x*ₖ (=x_{INT(k)}) stored at the address INT(k) of the channel value memory 2A and the value y2ₖ stored in the channel value memory 2C via the channel value memory interface 11, along with the external value Le*ₖ (=Le_{INT(k)}) stored in the address INT(k) of the external value memory 5 via the external value memory interface 18. In this case, the channel value memory interface 11 refers to its own interleave table 11a to read the channel values x_{INT(k)} as the channel values x*ₖ. Likewise, the external value memory interface 18 refers its own interleave table 18a to read the external value Le_{INT(k)} as the external value Le*ₖ (step ST3).

The transition probability calculating circuit 12, using the external values Le*ₖ as the prior values La*ₖ, calculates the transition probabilities γₖ(m* , m) of individual forward state transitions from the prior values Laₖ and the channel values x*ₖ and y2ₖ by the foregoing Expressions (3) and (4) (with replacing y1ₖ in Expression (3) by y2ₖ), and supplies them to the path probability calculating circuit 13.

The path probability calculating circuit 13 calculates the forward path probabilities αₖ(m) (m=0, 1, 2, 3) at the point of time k from the transition probabilities γₖ₋₁(m*, m) and the forward path probabilities αₖ₋₁(m*) (m=0, 1, 2, 3) at the previous point of time (k−1) stored in the memory circuit 14 by the foregoing Expression (5), and stores them into the memory circuit 14.

The memory circuit 14 delays the forward path probabilities αₖ(m) calculated by the path probability calculating circuit 13 by the period of the points of time, and supplies them to the path probability calculating circuit 13 and the path metric memory 15 to be stored at its addresses k.

Subsequently, after calculating the final forward path probabilities α_{N}(m) (m 0, 1, 2, 3), the path probability calculating circuit 13 successively calculates the reverse path probabilities βₖ(m) from k=N−1 to k=1. Incidentally, the final forward path probabilities α_{N}(m) (m=0, 1, 2, 3) are also supplied to the initial value setting circuit 19 of the decoder 4B to be stored.

In this case, before starting the calculation of the reverse path probabilities βₖ(m), the initial value setting circuit 19 sets in the memory circuit 14 their initial values at β_{N}(m)=¼ (m=0, 1, 2, 3) in the first decoding, and at β_{N}(m) (m=0, 1, 2, 3) that are calculated in the previous decoding of the second block B22 of the second received code sequence in the second and the following decoding.

In the calculation of the reverse path probabilities βₖ(m), the transition probability calculating circuit 12 captures, at each point of time k, the value x*ₖ (=x_{INT(k)}) stored at the address INT(k) of the channel value memory 2A and the value y2ₖ stored in the channel value memory 2C via the channel value memory interface 11, along with the external value Le*ₖ (=Le_{INT(k)}) stored in the address INT(k) of the external value memory 5 via the external value memory interface 18. In this case, the channel value memory interface 11 refers to its own interleave table 11a to read the channel value x_{INT(k)} as the channel value x*ₖ. Likewise, the external value memory interface 18 refers to its own interleave table 18a to read the external value Le_{INT(k)} as the external value Le*ₖ (step ST3).

The transition probability calculating circuit 12, using the external values Le*ₖ as the prior values La*ₖ, calculates the transition probabilities γₖ(m, m*) of the individual reverse state transitions from the prior values La*ₖ and the channel values x*ₖ and y2ₖ by the foregoing Expressions (3) and (4) (with replacing y1ₖ in Expression (3) by y2ₖ), and supplies them to the path probability calculating circuit 13 and the posterior value calculating circuit 16.

The path probability calculating circuit 13 calculates the reverse path probabilities βₖ(m) (m*=0, 1, 2, 3) at the point of time k from the transition probabilities γₖ(m, m*) and the reverse path probabilities βₖ₊₁(m*) (m=0, 1, 2, 3) at the subsequent point of time (k+1) stored in the memory circuit 14 by the foregoing Expression (8), and stores them into the memory circuit 14.

The memory circuit 14 delays the reverse path probabilities βₖ(m) calculated by the path probability calculating circuit 13 by the period of the points of time, and supplies them to the path probability calculating circuit 13 and the posterior value calculating circuit 16.

Thus, at the point of time k, the posterior value calculating circuit 16 is supplied with the reverse path probabilities βₖ₊₁(m) from the memory circuit 14, the transition probabilities γₖ(m, m*) from the transition probability calculating circuit 12, and the forward path probabilities αₖ(m) (m=0, 1, 2, 3) stored at the addresses k of the path metric memory 15. Here, the reverse path probabilities βₖ(m) are successively calculated from k=N−1 to k=1.

The posterior value calculating circuit 16 calculates the posterior values L*ₖ from the forward path probabilities αₖ(m) (m=0, 1, 2, 3), the reverse path probabilities βₖ₊₁(m*) (m*=0, 1, 2, 3) and the transition probabilities γₖ(m, m*) (m, m* =0, 1, 2, 3) by the foregoing Expression (11), and supplies them to the external value calculating circuit 17.

The external value calculating circuit 17 calculates each external value Le*ₖ by subtracting the channel value Lc·x*ₖ and prior value La*ₖ from the posterior value L*ₖ, and writes the resultant external values to the addresses INT(k) of the external value memory 5 via the external value memory interface 18. In this case, the external value memory interface 18 refers to its own interleave table 18a to write the external values Le*ₖ to the addresses INT(k).

In this way, the decoder 4A decodes the first block B21 of the second received code sequence, thereby generating the external values Le*ₖ (k=0, 1, . . . , N−1).

Finally, the operation of the decoder 4B to decode the second block B22 of the second received code sequence (step ST4B) will be described. Using the interleaved values of the external values Leₖ, which are generated from the first received code sequence, as the prior values La*ₖ, the decoder 4B carries out the MAP decoding of the second block B22={X22, Y22} of the second received code sequence in the same manner as it decodes the second block B12 of the first received code sequence.

First, the initial value setting circuit 19 sets in the memory circuit 14 the initial values of the forward path probabilities at α_{N}(m)=¼ (m=0, 1, 2, 3) in the first decoding, and at α_{N}(m) (m=0, 1, 2, 3) calculated in the previous decoding of the first block B21 of the second received code sequence in the second and subsequent decoding.

Subsequently, for each step from k=N to k=2N+1in sequence, the transition probability calculating circuit 12 captures the value x*ₖ (=x_{INT(k)}) stored at the address INT(k) of the channel value memory 2A and the value y2ₖ stored in the channel value memory 2C via the channel value memory interface 11, along with the external value Le*ₖ (=Le_{INT(k)}) stored in the address INT(k) of the external value memory 5 via the external value memory interface 18. In this case, the channel value memory interface 11 refers to its own interleave table 11a to read the channel value x_{INT(k)} as the channel value x*ₖ. Likewise, the external value memory interface 18 refers to its own interleave table 18a to read the external value Le_{INT(k)} as the external value Le*ₖ (step ST3). In this case, however, it reads the channel value x*_{2N} stored at address 2N+2 in the channel value memory 2A at k=2N, and the channel value x*_{2N+1} stored in address 2N+3 at k=2N+1.

The transition probability calculating circuit 12, using the external values Le*ₖ as the prior values La*ₖ, calculates the transition probabilities γₖ(m*, m) of the individual forward state transitions from the prior values La*ₖ and the channel values x*ₖ and y2ₖ by the foregoing Expressions (3) and (4), and supplies them to the path probability calculating circuit 13. Here, the prior values of the additional information bits are placed at zero.

The path probability calculating circuit 13 calculates the forward path probabilities αₖ(m) (m=0, 1, 2, 3) at the point of time k from the transition probabilities γₖ₋₁(m*, m) and the previous forward path probabilities αₖ₋₁(m*) (m*=0, 1, 2, 3) stored in the memory circuit 14 by the foregoing Expression (5), and stores them into the memory circuit 14.

The memory circuit 14 delays the forward path probabilities αₖ(m) calculated by the path probability calculating circuit 13 by the period of the points of time, and supplies them to the path probability calculating circuit 13 and the path metric memory 15 to be stored at its addresses k.

Subsequently, after calculating the final forward path probabilities a α_{2N+1}(m), the path probability calculating circuit 13 successively calculates the reverse path probabilities βₖ(m) from k=2N+1 to k=N. The final reverse path probabilities β_{N}(m) are also supplied to the initial value setting circuit 19 of the decoder 4A to be stored.

In this case, before starting the calculation of the reverse path probabilities βₖ(m), the initial value setting circuit 19 sets their initial values at β_{2N+2}(0)=1 and β_{2N+2}(m)=0 (m=1, 2, 3) in the memory circuit 14.

In the calculation of the reverse path probabilities βₖ(m), the transition probability calculating circuit 12 captures the channel values x*ₖ (=x_{INT(k)}) stored in the channel value memory 2A and the channel values y2ₖ stored in the channel value memory 2C via the channel value memory interface 11, along with the external values Le*ₖ stored in the addresses INT(k) of the external value memory 5 via the external value memory interface 18. In this case, the channel value memory interface 11 refers to its own interleave table 11a to read the channel values x_{INT(k)} as the channel values x*ₖ. Likewise, the external value memory interface 18 refers to its own interleave table 18a to read the external values Le_{INT(k)} as the external values Le*ₖ (step ST3).

The transition probability calculating circuit 12, using the external values Le*ₖ as the prior values La*ₖ, calculates the reverse transition probabilities γₖ(m, m*) from the prior values La*ₖ and channel values x*ₖ and y2ₖ, and supplies them to the path probability calculating circuit 13 and the posterior value calculating circuit 16.

The memory circuit 14 delays the reverse path probabilities βₖ(m) calculated by the path probability calculating circuit 13 by the period of the points of time, and supplies them to the path probability calculating circuit 13 and the posterior value calculating circuit 16.

Thus, at the point of time k, the posterior value calculating circuit 16 is supplied with the reverse path probabilities βₖ₊₁(m) from the memory circuit 14, the transition probabilities γₖ(m, m*) from the transition probability calculating circuit 12, and the forward path probabilities αₖ(m) stored at the address k of the path metric memory 15. The reverse path probabilities βₖ(m) are successively calculated from k=2N+1 to k=N.

The posterior value calculating circuit 16 calculates the posterior values L*ₖ from these forward path probabilities αₖ(m), reverse path probabilities βₖ₊₁(m*) and transition probabilities γₖ(m, m*) by the foregoing Expression (11), and supplies them to the external value calculating circuit 17.

The external value calculating circuit 17 calculates each external value Le*ₖ by subtracting the channel value Lc·x*ₖ and prior value La*ₖ from the posterior value L*ₖ, and writes the resultant external values Le*ₖ into the addresses INT(k) of the external value memory 5 via the external value memory interface 18. In this case, the external value memory interface 18 refers to its own interleave table 18a to write the external values Le*ₖ into the addresses INT(k).

In this way, the decoder 4B decodes the second block B22 of the second received code sequence, thereby generating the external values Le*ₖ (k=N, N+1, . . . , 2N−1). Here, the external values of the additional information bits are not calculated.

Thus, the first decoding of the turbo-code sequence is carried out, resulting in the external values Le*ₖ (k=0, 2N−1) and the posterior values L*ₖ (k=0, . . . , 2N−1). The external values Le*ₖ (k=0, . . . , 2N−1) are stored at the addresses INT(k) of the external value memory 5, which means that the external values Le₀−Le_{2N-1} are stored at the addresses 0−2N−1 of the external value memory 5. Accordingly, it is not necessary for the external values to be deinterleaved when they are read as the prior values in the next decoding. In the final decoding of the blocks B21 and B22, the posterior value calculating circuit 16 outputs the posterior values via the input/output interface 1 as the decoded results.

Thus, the decoders 4A and 4B decode in parallel the first block B11 of the first received code sequence and the second block B12 of the first received code sequence, and the first block B21 of the second received code sequence and the second block B22 of the second received code sequence.

As described above, the present embodiment 1 is configured such that it divides the received code sequence into a plurality of blocks along the time axis, and decodes n (at least two) blocks in parallel. This offers an advantage of being able to reduce the decoding time by a factor of n, where n is the number of the blocks decoded in parallel.

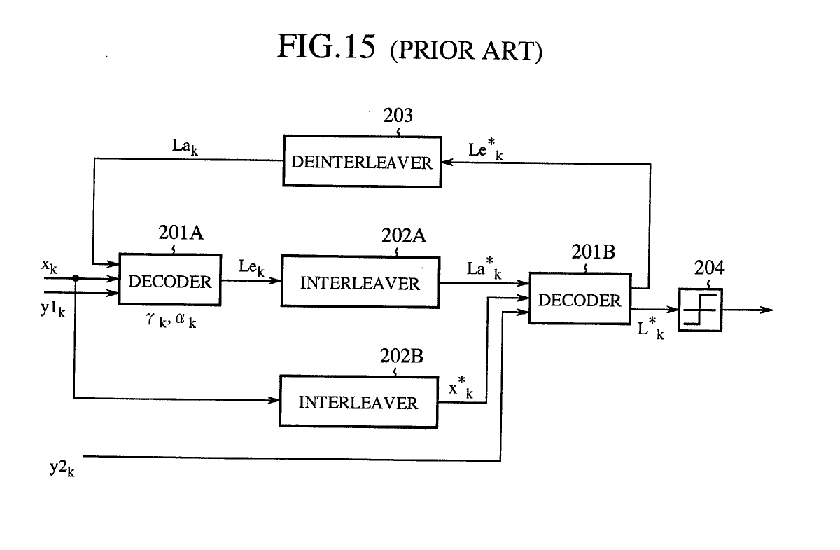

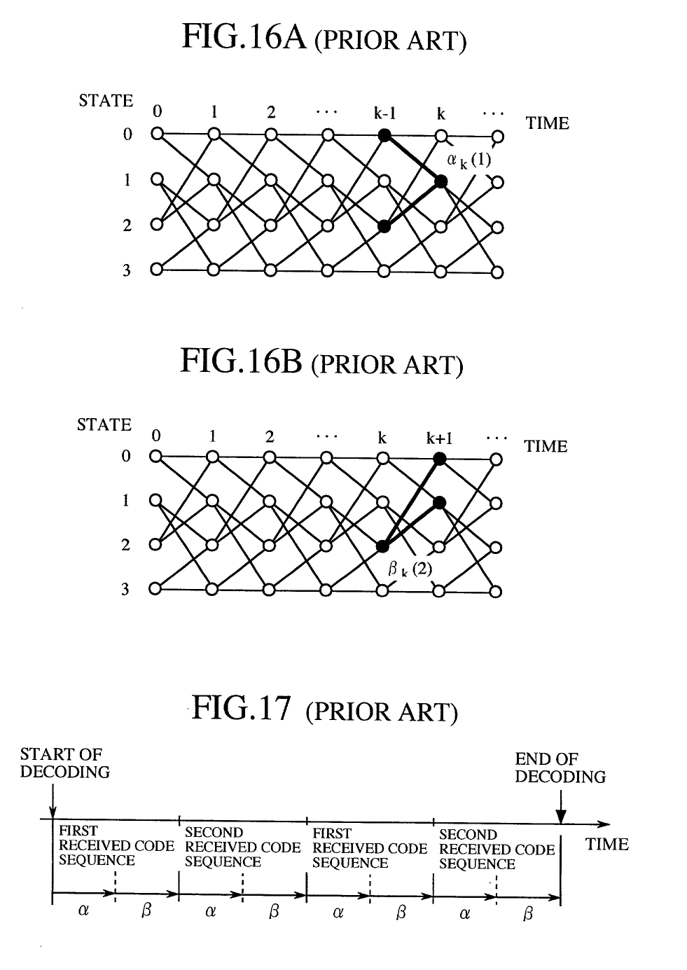

The decoding unit (FIG. 1) of the present embodiment 1 is comparable to the conventional decoding unit (FIG. 15) in the circuit scale and memory capacity, achieving faster decoding with a similar circuit scale.

### EMBODIMENT 2

An encoder of an embodiment 2 in accordance with the present invention can generate a turbo-code sequence at any desired coding rate by puncturing; and a decoding unit of the embodiment 2 decodes the turbo-code sequence with the punctured coding rate. It is assumed here that the coding rate of the turbo-code is 1/2.

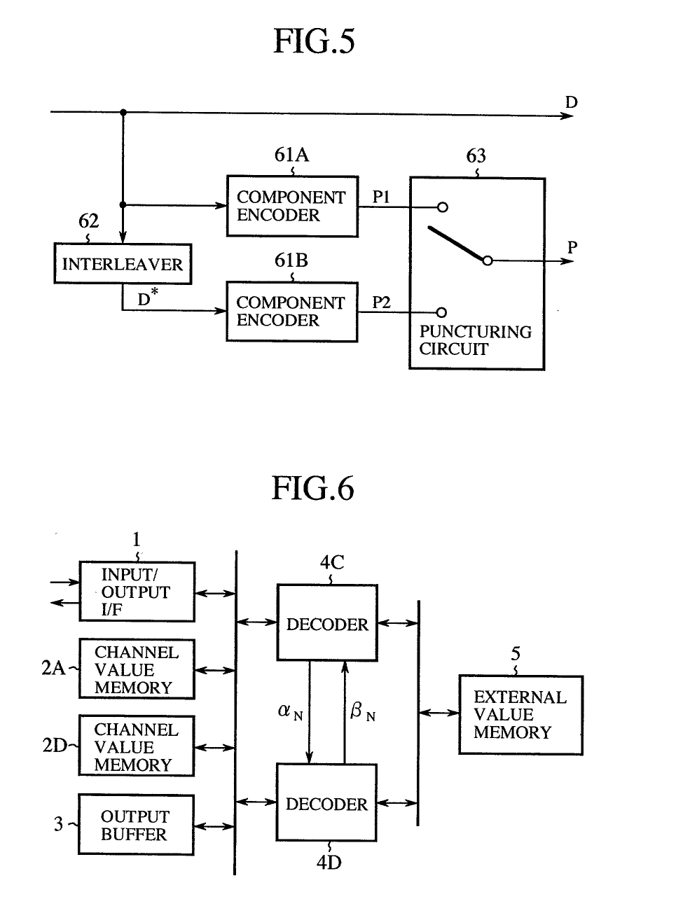

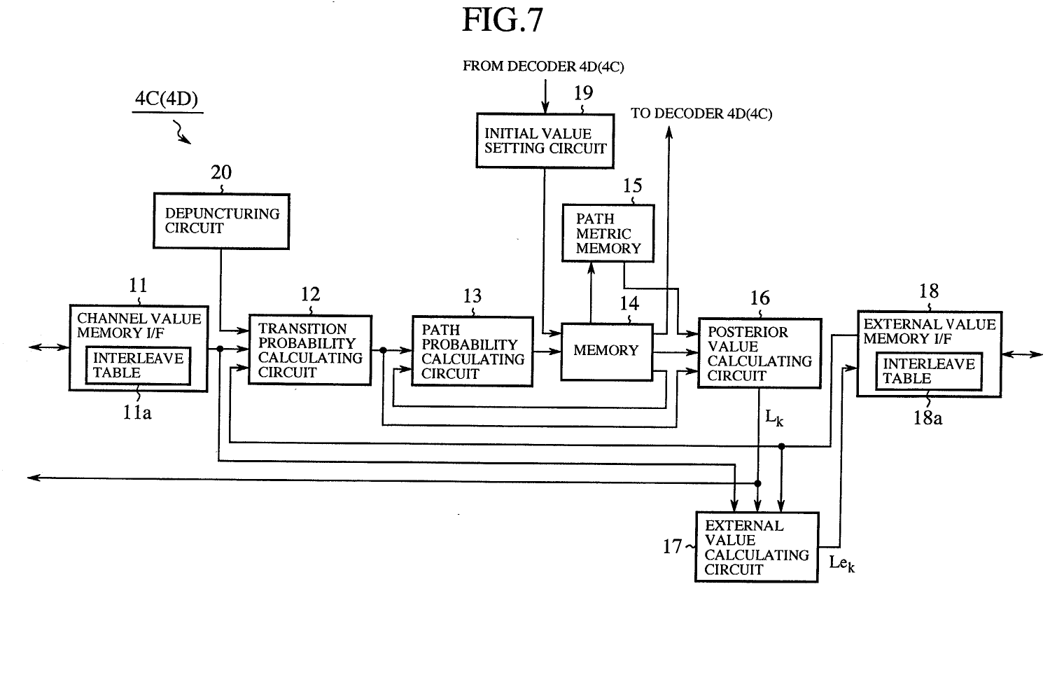

FIG. 5 is a block diagram showing a configuration of an encoder of the present embodiment 2 in accordance with the present invention; FIG. 6 is a block diagram showing a configuration of a decoding unit of the embodiment 2; and FIG. 7 is a block diagram showing a configuration of a decoder of FIG. 6.

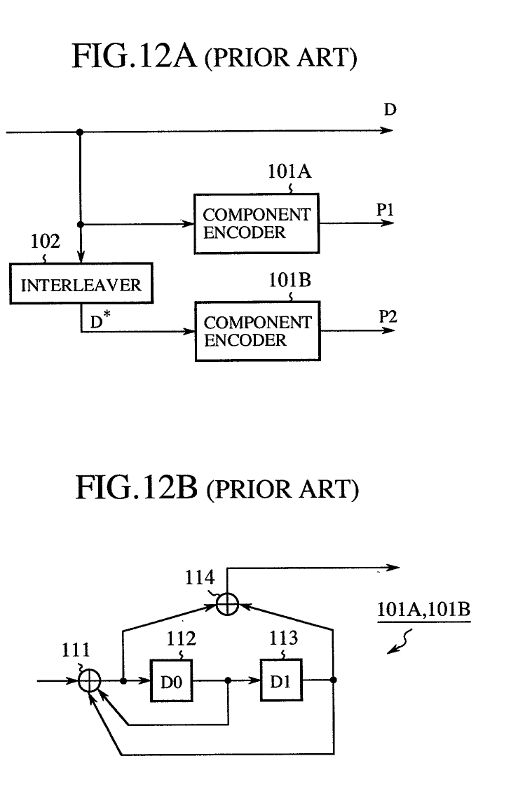

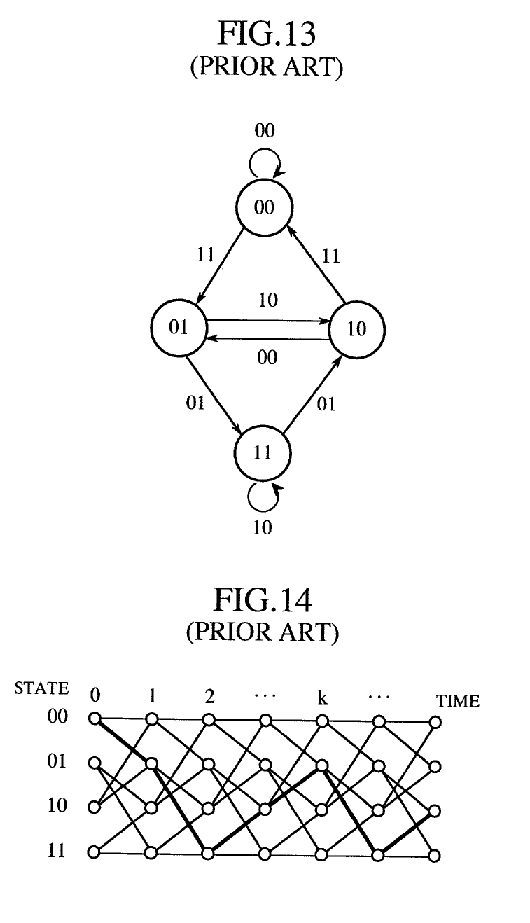

In the encoder as shown in FIG. 5, the reference numeral 61A designates a component encoder for generating a first parity bit sequence P1 from an information bit sequence D; 61B designates a component encoder for generating a second parity bit sequence P2 from an information bit sequence D* generated by rearranging the information bit sequence D by an interleaver 62; 62 designates the interleaver for mixing the bits dᵢ of the information bit sequence D according to a prescribed mapping to generate the information bit sequence D*; and 63 designates a puncturing circuit for puncturing the first and second parity bit sequences P1 and P2 to generate a parity bit sequence P. The component encoders 61A and 61B are the same as the component encoder shown in FIG. 12B.

In the decoding unit as shown in FIG. 6, the reference numeral 2A designates a channel value memory for storing channel values X input through the input/output interface 1; 2D designates a channel value memory for storing channel values Y={yₖ (k=0, 1, . . . , 2N−1)}, a received sequence of the parity bit sequence P input via the input/output interface 1; and reference numerals 4C and 4D designate decoders for performing parallel soft input/soft output decoding of a plurality of blocks constituting the received sequence of the punctured turbo-code sequence. Since the remaining configuration of FIG. 6 is the same as that of the embodiment 1 (FIG. 1) the description thereof is omitted here.

In the decoder 4C or 4D as shown in FIG. 7, the reference numeral 20 designates a depuncturing circuit for supplying the transition probability calculating circuit 12 with predetermined values in place of the channel values corresponding to the parity bits discarded by the puncturing. Since the remaining configuration of FIG. 7 is the same as that of the embodiment 1 (FIG. 2), the description thereof is omitted here.

Next, the operation of the present embodiment 2 will be described.

First the operation of the encoder as shown in FIG. 5 will be described.

The encoder produces a turbo-code sequence with a coding rate of 1/3 from the information bit sequence D, first parity bit sequence P1 and second parity bit sequence P2. The puncturing circuit 63 alternately selects parity bits p1ₖ and p2^{k} of the two parity bit sequences P1 and P2, and outputs them as the parity bit sequence P, thereby producing the turbo-code sequence with a coding rate of 1/2.

The information bit sequence D is supplied to the component encoder 61A and the interleaver 62, and the information bit sequence D* generated by the interleaver 62 is supplied to the component encoder 61B.

At each point of time t=k (k=0, 1, . . . , 2N−1), the component encoder 61A generates the first parity bit p1ₖ from the information bit, and the component encoder 61B generates the second parity bit p2^{k}, and these parity bits are supplied to the puncturing circuit 63.

The puncturing circuit 63 alternately selects the first and second parity bits p1ₖ and p2^{k}, and outputs them as the parity bit sequence P. The parity bits of the tail bits, however, are not punctured, but output as they are. Accordingly, the entire bit sequences transmitted from the encoder consists of the information bit sequence D={dₖ (k=0, 1, . . . , 2N−1)}, the parity bit sequence P={p1₀, p2₁, p1², . . . , p2^{2N-3}, p1^{2N-2}, p2^{2N-1}}, and the tail bits {d_{2N}, d_{2N+1}, p1^{2N}, p1^{2N+1}, d*_{2N}, d*_{2N+1}, p2^{2N}, p2_{2N+1}}.

Thus, the puncturing circuit 63 outputs the punctured turbo-code sequence.

Next, the operation of the decoding unit as shown in FIGS. 6 and 7 will be described.

The decoding unit decodes the turbo-code sequence with a coding rate of 1/2. Assumed here that the received sequence of the information bit sequence D is {xₖ (k=0, 1, . . . , 2N−1)}, that of the parity bit sequence P is {yₖ (k=0, 1, . . . , 2N−1)}, and that of the tail bits {d_{2N}, d_{2N+1}, p1^{2N}, p1^{2N+1}, d*_{2N}, d*_{2N+1}, p2^{2N}, p2_{2N+1}} is {x_{2N}, x_{2N+1}, y_{2N}, y_{2N+1}, x*_{2N}, x*_{2N+1}, y*_{2N}, y*_{2N+1}}. let us define the sequences X and Y as X={xₖ (k=0, 1, . . . , 2N−1), x^{2N}, x^{2N}, x*_{2N}, x*_{2N+1}}, and Y={yₖ (k=0, 1, . . . , 2N−1), y_{2N}, y_{2N+1}, y*_{2N}, y*_{2N+1}}.

The received turbo-code sequences X and Y are input via the input/output interface 1, and the sequence X is stored in the channel value memory 2A, and the sequence Y in the channel value memory 2D.

Just as the decoders 4A and 4B in the foregoing embodiment 1, the decoders 4C and 4D performs the MAP decoding of the first received code sequence {X1, Y1} and the second received code sequence {X2, Y2} consisting of the received sequences.

In this case, the decoders 4C and 4D generate the code sequences Y1 and Y2 by inserting the lowest reliable channel value in place of the punctured bits of the sequences Y1 and Y2 such as the code sequence Y1={y1ₖ=yₖ (when k is even), y1ₖ=0 (when k is odd), y^{2N}, y^{2N+1}}, and Y2={y2ₖ=0 (when k is even), y2ₖ=yₖ (when k is odd), y*_{2N}, y*_{2N+1}}, where “0”represents the lowest reliable channel value.

When decoding the first received code sequence by the decoders 4C and 4D, the transition probability calculating circuit 12 captures the value y1ₖ stored at the address k of the channel value memory 2D at even points of time k, and the value y1ₖ=0 (the least reliable channel value) from the depuncturing circuit 20 at odd points of time k without reading any channel value from the channel value memory 2D. On the other hand, when decoding the second received code sequence, the transition probability calculating circuit 12 captures the value y2ₖ=0 (the least reliable channel value) from the depuncturing circuit 20 at even points of time k without reading any channel value from the channel value memory 2D, and the value y2ₖ stored at the address k of the channel value memory 2D at odd points of time k.

Since the remaining operation of the decoding unit is the same as that of the foregoing embodiment 1, the description thereof is omitted here.

As described above, the present embodiment 2 comprises in the decoders 4C and 4D the depuncturing circuit 20 for inserting the lowest reliable value in place of the channel values corresponding to the punctured bits of the punctured received code sequence. Accordingly, it offers an advantage of being able to achieve high-speed decoding of the turbo-code sequence with a coding rate increased by the puncturing, in the same manner as the foregoing embodiment 1.

Furthermore, the present embodiment 2 is configured such that it interleaves the information bit sequence, generates the parity bit sequences from the information bit sequence and the interleaved sequence, and reduces the number of bits of the parity bit sequences by puncturing the parity bit sequences. Therefore, it offers an advantage of being able to generate the punctured turbo-code sequence with a predetermined coding rate simply.

Incidentally, although the present embodiment 2 punctures the turbo-code sequence with the coding rate of 1/3 to that with the coding rate of 1/2, this is not essential. The turbo-code sequence with any coding rate can be punctured to that with any other coding rate.

### EMBODIMENT 3

The decoding unit of an embodiment 3 in accordance with the present invention is characterized by carrying out decoding in parallel with writing of the channel values to the channel value memories 2A, 2B and 2C, that is, without waiting for the completion of writing the channel values. Since the configuration of the decoding unit of the present embodiment 3 is the same as that of the embodiment 1, the description thereof is omitted here. Only, instead of the decoders 4A and 4B, decoders 4C and 4D with the following functions are used.

Next, the operation of the present embodiment 3 will be described.

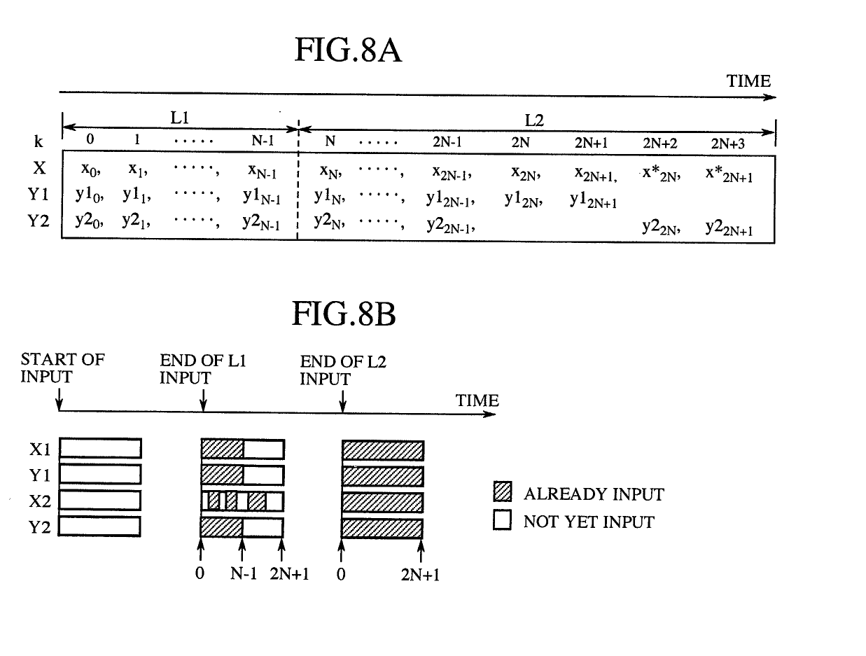

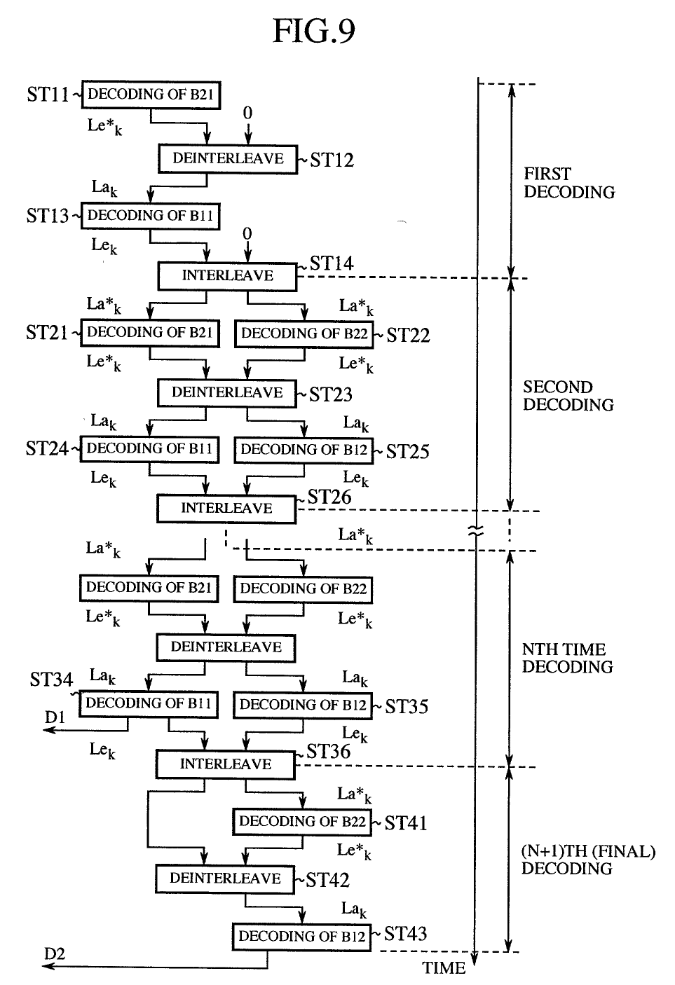

FIGS. 8A and 8B are timing charts illustrating the input state of received sequences X, Y1 and Y2 to the decoding unit of the present embodiment 3; and FIG. 9 is a flowchart illustrating the operation of the decoding unit of the embodiment 3.

At each point of time k (k=0, 1, . . . , 2N−2, 2N−1), the channel values xₖ, Y1ₖ and y2ₖ of the received sequence X, Y1 and Y2 are input through the input/output interface 1.

As to the tail bits, however, the channel values x_{2N} and y1_{2N} are input at the point of time 2N, x_{2N+1} and y1_{2N+1} are input at the point of time 2N+1, x*₂ N and y2_{2N} are input at the point of time 2N+2, and x*_{2N+1} and y2_{2N+1} are input at the point of time 2N+3.

As shown in FIG. 8A, the received code sequences are divided into blocks L1 and L2. The length of the block L1 is N, and that of the block L2 is N+4 because it includes the tail bits.

In this case, the block L1 is input, followed by the input of the block L2. At the end of the input of the block L1, the input of the first block B11{X11, Y11} of the first received code sequence has been completed as shown in FIG. 8B. At that time, as for the first block B21={X21, Y21} of the second received code sequence, although the input of the sequence Y21 has been completed, the sequence X21 has been input about half its amount because it is an interleaved sequence.

Afterward, at the end of the input of the block L2, the input of all the sequences X, Y1 and Y2 has been completed as shown in FIG. 8B. In other words, the input has been completed of the first block B11 of the first received code sequence, the second block B12 of the first received code sequence, the first block B21 of the second received code sequence and the second block B22 of the second received code sequence.

As shown at the top of FIG. 9, after completing the input of the block L1, the decoder 4C carries out the MAP decoding of the first block B21 of the second received code sequence with placing the prior values La*ₖ at zero (ST11), thereby calculating the external value Le*ₖ (k=0, 1, , N−1) . Here, as for the channel values of the sequence X21 of the first block B21 of the second received code sequence that have not yet been input, they are assigned the lowest reliability value “0” by the depuncturing circuit 20. On the other hand, since the second block B22 of the second received code sequence has not yet been input at this point of time, the external values Le*ₖ (k=N, N+1, . . . , 2N−1) are placed at zero.

Deinterleaving these external values Le*ₖ generates the prior values Laₖ (k=0, 1, . . . , 2N−1) for the MAP decoding of the first received code sequence (ST12).

Subsequently, using the prior values Laₖ, the decoder 4C carries out the MAP decoding of the first block B11 of the first received code sequence (ST13), thereby calculating the external values Leₖ (k=0, 1, . . . , N−1). At this point of time, since the first block B11 of the first received code sequence has been input in its entirety, the depuncturing is not necessary. On the other hand, since the second block B12 of the first received code sequence has not yet been input, it is not decoded and the corresponding external values Leₖ (k=N, N+1, . . . , 2N−1) are placed at zero.

Interleaving the external values Leₖ generates the prior values La*ₖ (k=0, 1, . . . , 2N−1) for the MAP decoding of the second received code sequence (ST14).

Thus, the first decoding has been completed which uses the channel values supplied as the block L1, that is, the first half of the received code sequence X, Y1 and Y2.

Next, after completing the input of the block L2, the decoder 4C carries out the MAP decoding of the first block B21 of the second received code sequence (ST21) using the prior values La*ₖ (k=0, 1, . . . , N−1) calculated in the first decoding, thereby generating the external values Le*ₖ (k=0, 1, . . . , N−1)}. In parallel with this, the decoder 4D carries out the MAP decoding of the second block B22 of the second received code sequence (ST22) using prior values La*ₖ(k=N, N+1, . . . , 2N−1), thereby generating the external values Le*ₖ (k=N, N+1, . . . , 2N−1).

Subsequently, deinterleaving these external values Le*ₖ generates the prior values Laₖ (k=0, 1, . . . , 2N−1) for the MAP decoding of the first received code sequence (ST23).

Afterward, the decoder 4C carries out the MAP decoding of the first block B11 of the first received code sequence (ST24) using the first half prior values Laₖ (k=0, 1, . . . , N−1), thereby generating the external values Leₖ (k=0, 1, . . . , N−1). In parallel with this, the decoder 4D carries out the MAP decoding of the second block B12 of the first received code sequence (ST25) using the second half prior values Laₖ (k=N, N+1, . . . , 2N−1), thereby generating the external values Leₖ (k=N, N+1, . . . , 2N−1).

Interleaving these external values Leₖ generates the prior values La*ₖ (k=0, 1, . . . , 2N−1) for the MAP decoding of the second received code sequence (ST26).

Thus, the second decoding has been completed using the channel values of the blocks L1 and L2, that is, all the received sequences X, Y1 and Y2.

Since the successive decoding is the same as the second decoding, the description thereof is omitted here.

In the Nth decoding immediately before the final decoding, the decoder 4C carries out the MAP decoding of the first block B11 of the first received code sequence (ST34), thereby generating the posterior values Lₖ (k=0, 1, . . . , N−1) corresponding to the first half D1={dₖ} of the information bit sequence D.

In the final (N+1)th decoding, the decoder 4D carries out the MAP decoding of the second block B22 of the second received code sequence (ST41) using the prior values La*ₖ (k=N, N+1, . . . , 2N−1) generated in the Nth decoding, thereby generating the external values Le*ₖ (k=N, N+1, . . . , 2N−1). Here, the MAP decoding of the first block B21 of the second received code sequence is not carried out, and the prior values La*ₖ (k=0, 1, . . . , N−1) supplied are simply adopted as the external values Le*ₖ (k=0, 1, . . . , N−1) without change.

Deinterleaving these external values Le*ₖ generates the prior values Laₖ (k=0, 1, . . . , 2N−1) for the MAP decoding of the first received code sequence (ST42).

Subsequently, the decoder 4D carries out the MAP decoding of the second block B12 of the first received code sequence (ST43) using the second half prior values Laₖ (k=N, N+1, . . . , 2N−1)}, thereby generating the posterior values Lₖ (k=N, N+1, . . . , 2N−1) corresponding to the second half D2={dₖ} of the information bit sequence D to be output. In this case, the MAP decoding of the first block B11 of the first received code sequence is not carried out.

Thus, the decoding is repeated N times for each of the first and second halves of the information bit sequence to calculate the estimated values.

As described above, the present embodiment 3 is configured such that it starts its decoding at the end of the input of each block, and outputs the posterior values corresponding to the channel values successively beginning from the first block. Thus, it offers an advantage of being able to start its decoding before completing the input of all the received code sequences, and hence to reduce the time taken for the decoding.

Furthermore, the present embodiment 3 is configured such that it generates the posterior values from the block that has not yet been input (B21 in the present example) so that it can use the prior values corresponding to the posterior values as the prior values for decoding the block that has already been input (B11 in the present example). Thus, it has an advantage of being able to use the prior values more accurate than the prior values placed at zero.

Incidentally, it is preferable for the turbo-code information bit sequence to be arranged such that more important information bits or more time-consuming information bits that takes much time for the post-processing after the decoding are placed on the initial side of the sequence because these information bits are decoded first.

### EMBODIMENT 4

The decoding unit of the present embodiment 4 in accordance with the present invention is configured such that it divides the turbo-code sequence into a plurality of blocks, and that a single decoder carries out the MAP decoding of the individual blocks successively, thereby completing the MAP decoding of the entire code.

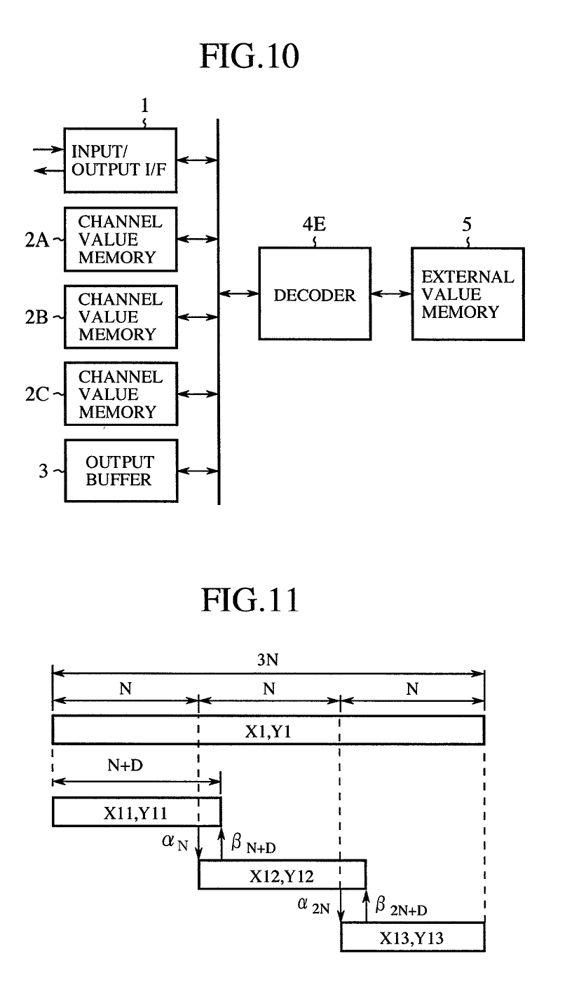

FIG. 10 is a block diagram showing a configuration of the decoding unit of the present embodiment 4 in accordance with the present invention. In FIG. 10, the reference numeral 4E designates a decoder for carrying out the MAP decoding the divided blocks in succession. Since the remaining configuration of FIG. 10 is the same as that of the embodiment 1, the description thereof is omitted here. In addition, since the decoder 4E has the same configuration as the decoder 4A as shown in FIG. 2 except that its path probabilities α_{N}(m) and β_{N}(m) fed from the memory circuit 14 are supplied to its own initial value setting circuit 19 to be held therein instead of being transferred to the other decoder, the description thereof is omitted here.

Next, the operation of the present embodiment 4 will be described.

FIG. 11 is a diagram illustrating a relationship between the first received code sequence and the blocks, in which the code length is assumed to be 3N including the tail bits for the sake of simplicity.

From the first received code sequence {X1, Y1}, the following three first sub-sequences that overlap each other by a length D are defined as follows.

X11={xₖ(k=0, 1, . . . , N−1, N, . . . , N+D−1)}

X12={xₖ(k=N, N+1, . . . , 2N−1, 2N, . . . , 2N+D−1)}

X13={xₖ(k=2N, 2N+1, . . . , 3N−1)}

Y11={y1ₖ(k=0, 1, . . . , N−1, N, . . . , N+D−1)}

Y12={y1ₖ(k=N, N+1, . . . , 2N−1, 2N, . . . , 2N+D−1)}

Y13={y1ₖ(k=2N, 2N+1, . . . , 3N−1)}

where D is the length of the overlapped section, which length D is preferably set at eight to ten times the constraint length. The sub-sequences {X11, Y11} is called the first block, the sub-sequences {X12, Y12} are called the second block, and the sub-sequences {X13, Y13} are called the third block.

The decoder 4E carries out the MAP decoding of the first block {X11, Y11}, second block {X12, Y12} and third block {X13, Y13} in succession. It generates the external values Leₖ (k=0, 1, . . . , N−1) of the information bits dₖ (k=0, 1, . . . , N−1) by decoding the first block, the external values Leₖ (k=N, N+1, . . . , 2N−1) of the information bits dₖ (k=N, N+1, . . . , 2N−1) by decoding the second block, and the external values Leₖ (k=2N, 2N+1, . . . , 3N−1) of the information bits dₖ (k=2N, 2N+1, . . . , 3N−1) by decoding the third block.

In this case, the initial value setting circuit 19 writes the forward path probabilities α_{N}(m) (m=0, 1, 2, 3) obtained in the first block decoding into the memory circuit 14 as the initial values α_{N}(m) of the forward path probabilities for decoding the second block, and the forward path probabilities α_{2N}(m) (m=0, 1, 2, 3) obtained in the second block decoding as the initial values α₂N(m) of the forward path probabilities for decoding the third block.

Likewise, the initial value setting circuit 19 writes the reverse path probabilities β_{N+D}(m) (m=0, 1, 2, 3) obtained in the second block decoding into the memory circuit 14 as the initial values β_{N+D}(m) of the reverse path probabilities for decoding the first block, and the reverse path probabilities β_{2N+D}(m) (m=0, 1, 2, 3) obtained in the third block decoding as the initial values β_{2N+D}(m) of the reverse path probabilities for decoding the second block.

Next, the decoding of the individual blocks will be described in detail.

In the decoding of the first block, the initial values of the forward path probabilities are set at α₀(0)=1 and α₀(m)=0 (for m=1, 2, 3). Then, the path probability calculating circuit 13 calculates the forward path probabilities αₖ(m) successively from k=0 to k=N+D according to the forward recursive expression, and stores them into the path metric memory 15.

Completing the calculation of the forward path probabilities, the path probability calculating circuit 13 calculates the reverse path probabilities βₖ(m) from k=N+D to k=1 in succession. As for the initial values β_{N+D}(m) of the reverse path probabilities, β_{N+D}(m) ¼ are set (for m=0, 1, 2, 3) in the first decoding, whereas β_{N+D}(m) (m=0, 1, 2, 3) calculated in the previous decoding of the second block are set in the second and following decoding.

From the reverse path probabilities and the forward path probabilities stored in the path metric memory 15, the posterior value calculating circuit 16 and the external value calculating circuit 17 calculate the posterior values Lₖ (k=0, . . . , N+D−1) and the external values Leₖ (k=0, . . . , N−1) of the information bits dₖ (k=0, . . . , N+D−1). The external values Leₖ are stored in the external value memory 5. Here, the external values of the information bits dₖ (k=N, . . . , N+D−1) are not stored in the external value memory 5.

In the decoding of the second block, the forward path probabilities α_{N}(m) (m=0, 1, 2, 3) calculated in the decoding of the first block are set as their initial values, first. Then, the path probability calculating circuit 13 calculates the forward path probabilities αₖ(m) from k=N to k=2N+D in succession, and stores them into the path metric memory 15. At this point of time, since the forward path probabilities calculated in the first block decoding become unnecessary, the forward path probabilities calculated in the second block decoding can be overwritten thereon.

After completing the forward path probabilities, the path probability calculating circuit 13 calculates the reverse path probabilities βₖ(m) from k=2N+D to k=N in succession. As for the initial values β_{2N+D}(m) of the reverse path probabilities, β_{2N+D}(m)=¼ (m=0, 1, 2, 3) are set in the first decoding, and β_{2N+D}(m) (m=0, 1, 2, 3) obtained in the previous decoding of the third block are set in the second and subsequent decoding.

Subsequently, from the reverse path probabilities and the forward path probabilities stored in the path metric memory 15, the posterior value calculating circuit 16 and the external value calculating circuit 17 calculate the external values Leₖ (k=N, . . . , 2N−1) of the information bits dₖ, and store them into the external value memory 5. Here, the external values of the information bits dₖ (k=2N, . . . , 2N+D−1) are not stored in the external value memory 5.

In the decoding of the third block, the forward path probabilities α_{2N}(m) (m=0, 1, 2, 3) calculated in the second block decoding are set as their initial values, first. Then, the path probability calculating circuit 13 calculates the forward path probabilities αₖ(m) from k=2N to k=3N in succession, and stores them into the path metric memory 15. At this point of time, since the forward path probabilities calculated in the second block decoding become unnecessary, the forward path probabilities calculated in the third block decoding can be overwritten thereon.

After completing the forward path probabilities, the path probability calculating circuit 13 calculates the reverse path probabilities βₖ(m) from k=3N to k=2N in succession. As for the initial values of the reverse path probabilities, they are set at β_{3N}(0)=1 and β_{3N}(m)=0 (m=1, 2, 3).

Subsequently, from the reverse path probabilities and the forward path probabilities stored in the path metric memory 15, the posterior value calculating circuit 16 and the external value calculating circuit 17 calculate the posterior values Lₖ (k=2N, . . . , 3N−1) and external values Leₖ (k=2N, . . . , 3N−1) of the information bits dₖ (k=2N, . . . , 3N−1), and store the external values Leₖ (k=2N, . . . , 3N−1) into the external value memory 5.

Thus, the first decoding of the first received code sequence {X1, Y1} is completed. In the same way, the first decoding of the second received code sequence {X2, Y2} is carried out by dividing the second received code sequence {X2, Y2} into three blocks, and by decoding them sequentially.

Incidentally, providing the decoders 4C and 4D with the depuncturing circuit as in the foregoing embodiment 2 makes it possible to decode the punctured turbo-code.

As described above, the present embodiment 4 is configured such that it divides the received code sequence into a plurality of blocks along the time axis, and decodes the blocks in sequence. Thus, it offers an advantage of being able to reduce the capacity of the path metric memory for storing the forward path probabilities by a factor of n, where n is the number of the divisions (that is, blocks) of the received code sequence. Although the memory capacity of the channel value memory, external value memory and path metric memory increases in proportion to the code length in the turbo-code decoding, the present embodiment 4 can limit an increase in the memory capacity.

Furthermore, the present embodiment 4 divides the received code sequence into the blocks such that they overlap each other. Thus, it offers an advantage of being able to calculate the reverse path probabilities more accurately at the boundary of the blocks.

Although the decoders 4A-4E in the foregoing embodiments carry out the MAP decoding, they can perform other decoding schemes such as soft-output Viterbi algorithm and Log-MAP decoding, achieving similar advantages.

In addition, although the foregoing embodiments 1-3 divide each of the first and second received code sequences into two blocks, and decode them by the two decoders 4A and 4B (or 4C and 4D), the number of the divisions and the decoders is not limited to two, but can be three or more.

Moreover, although the embodiment 4 divides each of the first and second received code sequences into three blocks, the number of divisions is not limited to three.

What is claimed is:

1. A decoding unit for decoding a turbo-code sequence, said decoding unit comprising:
a plurality of decoders for dividing a received code sequence into a plurality of blocks along a time axis, and for decoding at least two of the blocks in parallel.

2. The decoding unit according to claim 1, wherein the received code sequence consists of a first received code sequence and a second received code sequence, wherein the first received code sequence consists of a received sequence of an information bit sequence and a received sequence of a first parity bit sequence generated from the information bit sequence, and the second received code sequence consists of a bit sequence generated by interleaving the received sequence of the information bit sequence, and a received sequence of a second parity bit sequence generated from a bit sequence generated by interleaving the information bit sequence, and wherein said decoding unit comprises a channel value memory for storing the first received code sequence and the received sequence of the second parity bit sequence.

3. The decoding unit according to claim 2, wherein said plurality of decoders comprise at least a first decoder and a second decoder, each of which comprises a channel value memory interface including an interleave table for reading each of the plurality of blocks of the first and second received code sequence from said channel value memory.

4. The decoding unit according to claim 3, wherein each of said plurality of decoders comprises:
a transition probability calculating circuit for calculating forward and reverse transition probabilities from channel values and prior values of each of the blocks;
a path probability calculating circuit for calculating forward path probabilities from the forward transition probabilities, and reverse path probabilities from the reverse transition probabilities;
a posterior value calculating circuit for calculating posterior values from the forward path probabilities, the reverse transition probabilities and the reverse path probabilities; and
an external value calculating circuit for calculating external values for respective information bits by subtracting from the posterior values the channel values and the prior values corresponding to the information bits.

5. The decoding unit according to claim 4, wherein each of said plurality of decoders further comprises:
means for supplying another of said decoders with one set of the forward path probabilities and the reverse path probabilities calculated finally; and
an initial value setting circuit for setting the path probabilities supplied from another decoder as initial values of the path probabilities.

6. The decoding unit according to claim 2, wherein the first parity bit sequence and the second parity bit sequence are punctured before transmitted, and wherein each of said decoders comprises a depuncturing circuit for inserting a value of least reliability in place of channel values corresponding to punctured bits of the received code sequences.

7. The decoding unit according to claim 4, wherein every time input of one of the blocks has been completed, each of said decoders starts decoding of the block, and outputs posterior values corresponding to the channel values of the block as posterior values corresponding to the information bits of the block.

8. The decoding unit according to claim 7, wherein at least one of said plurality of decoders decodes one of the blocks whose input has not yet been completed to generate posterior values of the block, and uses values corresponding to the posterior values as prior values of the block whose input has been completed.

9. A decoding unit for decoding a turbo-code sequence, said decoding unit comprising:
a decoder for dividing a received code sequence into a plurality of blocks along a time axis, and for decoding each of the blocks in sequence.

10. The decoding unit according to claim 9, further comprising a channel value memory for storing the received code sequence, wherein said decoder comprises:
a channel value memory interface for reading the received code sequence from said channel value memory block by block;
a transition probability calculating circuit for calculating forward and reverse transition probabilities from channel values and prior values of each of the blocks;
a path probability calculating circuit for calculating forward path probabilities from the forward transition probabilities, and reverse path probabilities from the reverse transition probabilities;
a posterior value calculating circuit for calculating posterior values from the forward path probabilities, the reverse transition probabilities and the reverse path probabilities; and
an external value calculating circuit for calculating external values for respective information bits by subtracting from the posterior values the channel values and the prior values corresponding to the information bits.

11. The decoding unit according to claim 10, wherein any adjacent blocks overlap each other by a predetermined length.

12. An encoding/decoding unit including an encoding unit for generating a turbo-code sequence from an information bit sequence, and a decoding unit for decoding a turbo-code sequence,
said encoding unit comprising:
a first component encoder for generating a first parity bit sequence from the information bit sequence;
an interleaver for interleaving the information bit sequence;
a second component encoder for generating a second parity bit sequence from an interleaved information bit sequence output from said interleaver; and
an output circuit for outputting the information bit sequence and the outputs of said first and second component encoders, and
said decoding unit comprising:
a plurality of decoders for dividing a first received code sequence and a second received code sequence into a plurality of blocks along a time axis, and for decoding at least two of the blocks in parallel, wherein the first received code sequence consists of a received sequence of the information bit sequence and a received sequence of the first parity bit sequence, and the second received code sequence consists of a bit sequence generated by interleaving the received sequence of the information bit sequence, and a received sequence of the second parity bit sequence; and
a channel value memory for storing the first received code sequence and the received sequence of the second parity bit sequence.
